(19) United States
(12) Patent Application Publication
(10) Pub. No.: US 2023/0295839 A1
(43) Pub. Date: Sep. 21, 2023

(54) GROUP III NITRIDE SUBSTRATE AND METHOD OF MAKING

(71) Applicant: SLT Technologies, Inc., Los Angeles, CA (US)

(72) Inventors: Keiji FUKUTOMI, Higashine-shi (JP); Wenkan JIANG, Walnut, CA (US); Motoi TAMAKI, Suita-shi (JP); Mark P. D'EVELYN, Vancouver, WA (US)

(73) Assignee: SLT Technologies, Inc., Los Angeles, CA (US)

(21) Appl. No.: 18/122,989

(22) Filed: Mar. 17, 2023

Related U.S. Application Data
(60) Provisional application No. 63/321,530, filed on Mar. 18, 2022.

(51) Int. Cl. C30B 29/40; H01L 33/00; H01L 21/02; C30B 7/10

(52) U.S. Cl. CPC C30B 29/406; H01L 33/0075; H01L 21/02389; C30B 7/105; H01L 21/02433

(57) ABSTRACT

Embodiments of the present disclosure include techniques related to techniques for processing materials for manufacture of group-III metal nitride and gallium based substrates. More specifically, embodiments of the disclosure include techniques for growing large area substrates using a combination of processing techniques. Merely by way of example, the disclosure can be applied to growing crystals of GaN, AlN, InN, InGaN, AlGaN, and AlInGaN, and others for manufacture of bulk or patterned substrates. Such bulk or patterned substrates can be used for a variety of applications including optoelectronic and electronic devices, lasers, light emitting diodes, solar cells, photo electrochemical water splitting and hydrogen generation, photodetectors, integrated circuits, and transistors, and others.

### CROSS-REFERENCE TO RELATED APPLICATIONS

This application claims benefit of U.S. provisional patent application Ser. No. 63/321,530, filed Mar. 18, 2022, which is herein incorporated by reference.

### BACKGROUND

### Field

This disclosure relates generally to techniques for processing materials for manufacture of gallium-containing nitride substrates and utilization of these substrates in optoelectronic and electronic devices. More specifically, embodiments of the disclosure include techniques for growing large area substrates using a combination of processing techniques.

### Description of the Related Art

Gallium nitride (GaN) based optoelectronic and electronic devices are of tremendous commercial importance. The quality and reliability of these devices, however, is compromised by high defect levels, particularly threading dislocations, grain boundaries, and strain in semiconductor layers of the devices. Threading dislocations can arise from lattice mismatch of GaN based semiconductor layers to a non-GaN substrate such as sapphire or silicon carbide. Grain boundaries can arise from the coalescence fronts of epitaxially-overgrown layers. Additional defects can arise from thermal expansion mismatch, impurities, and tilt boundaries, depending on the details of the growth of the layers.

The presence of defects has deleterious effects on epitaxially-grown layers. Such effects include compromising electronic device performance. To overcome these defects, techniques have been proposed that require complex, tedious fabrication processes to reduce the concentration and/or impact of the defects. While a substantial number of conventional growth methods for gallium nitride crystals have been proposed, limitations still exist. That is, conventional methods still merit improvement to be cost effective and efficient.

Progress has been made in the growth of large-area gallium nitride crystals with considerably lower defect levels than heteroepitaxial GaN layers. However, most techniques for growth of large-area GaN substrates involve GaN deposition on a non-GaN substrate, such as sapphire or GaAs. This approach generally gives rise to threading dislocations at average concentrations of 10⁵-10⁷ cm⁻² over the surface of thick boules, as well as significant bow, stress, and strain. Reduced concentrations of threading dislocations are desirable for a number of applications. Bow, stress, and strain can cause low yields when slicing the boules into wafers, make the wafers susceptible to cracking during down-stream processing, and may also negatively impact device reliability and lifetime. Another consequence of the bow, stress, and strain is that, during growth in m-plane and semipolar directions, even by near-equilibrium techniques such as ammonothermal growth, significant concentrations of stacking faults may be generated. In addition, the quality of c-plane growth may be unsatisfactory, due to formation of cracks, multiple crystallographic domains, and the like. Capability to manufacture substrates larger than 2 inches is currently very limited, as is capability to produce large-area GaN substrates with a nonpolar or semipolar crystallographic orientation. Most large area substrates are manufactured by vapor-phase methods, such as hydride vapor phase epitaxy (HVPE), which are relatively expensive. A less-expensive method is desired, while also achieving large area and low threading dislocation densities as quickly as possible.

Ammonothermal crystal growth has a number of advantages over HVPE as a means for manufacturing GaN boules. However, the performance of ammonothermal GaN crystal growth processing may be significantly dependent on the size and quality of seed crystals. Seed crystals fabricated by HVPE may suffer from many of the limitations described above, and large area ammonothermally-grown crystals are not widely available. A number of techniques, such as lateral epitaxial overgrowth (LEO) may be able to beneficiate HVPE-derived seed crystals, but may nonetheless suffer from issues with strain, cracking, and low yields. Several inventors, including Jiang, et al., (U.S. Pat. No. 9,589,792 and U.S. Patent Application 2021/0249252) have disclosed methods for applying LEO techniques to ammonothermal growth, but these methods have some limitations and improvements are warranted.

Due to at least the issues described above, there is a need for substrates that have a lower defect density and are formed by techniques that improve the crystal growth process. Also, from the above, it is seen that techniques for improving crystal growth are highly desirable.

### SUMMARY

Embodiments of the disclosure may provide a crystal, comprising a group Ill metal and nitrogen. The crystal is free-standing and comprises a wurtzite crystal structure, a first surface having a maximum dimension greater than 40 millimeters in a first direction, the first surface having a crystallographic orientation within 5 degrees of one of (0001) and (000-1), an average concentration of stacking faults below 10³ cm⁻¹; and an average concentration of threading dislocations between 10¹ cm⁻² and 10⁶ cm⁻², wherein the average concentration of threading dislocations on the first surface varies periodically by at least a factor of two in the first direction within a first domain, the period of the variation in the first direction being between 5 micrometers and 20 millimeters and the first domain having a maximum dimension in the first direction greater than 500 micrometers. The first surface comprises a plurality of first regions, each of the plurality of first regions having a locally-approximately-linear array of threading dislocations with a concentration between 5 cm⁻¹ and 10⁵ cm⁻¹, and at least 50% of intersections between neighboring locally-approximately-linear arrays of threading dislocations consist essentially of three locally-approximately-linear arrays of threading dislocations meeting at intersection angles of 120°±3°. The first surface further comprises a plurality of second regions, each of the plurality of second regions being disposed between an adjacent pair of the plurality of first regions and having a concentration of threading dislocations below 10⁵ cm⁻² and a concentration of stacking faults below 10³ cm⁻¹. The first surface further comprises a plurality of third regions, each of the plurality of third regions being disposed within one of the plurality of second regions or between an adjacent pair of second and having a minimum dimension between 10 micrometers and 500 micrometers and threading dislocations with a concentration between 10³ cm⁻² and 10⁸ cm⁻². The first domain is surrounded by six domains, in which the direction of between 55% and 100% of the plurality of third regions is oriented along a third direction, rotated by 60°±3° from the first direction, or along a fourth direction, rotated by 120°±3° from the first direction, where the direction of between 55% and 100% of the plurality of third regions within third domains in the six surrounding domains alternate between the third direction and the fourth direction.

Embodiments of the disclosure may provide a crystal, comprising a group Ill metal and nitrogen, wherein the crystal is free-standing and comprises a wurtzite crystal structure, a first surface having a maximum dimension greater than 5 millimeters in a first direction, the first surface having a crystallographic orientation within 5 degrees of one of (0001) and (000-1), an average concentration of stacking faults below 10³ cm⁻¹, and an average concentration of threading dislocations between 10¹ cm⁻² and 10⁶ cm⁻², wherein the average concentration of threading dislocations on the first surface varies periodically by at least a factor of two in the first direction within a first domain, the period of the variation in the first direction being between 5 micrometers and 20 millimeters and the first domain having a maximum dimension in the first direction greater than 500 micrometers. The first surface comprises a plurality of first regions, each of the plurality of first regions having a locally-approximately-linear array of threading dislocations with a concentration between 5 cm⁻¹ and 10⁵ cm⁻¹, and at least 50% of intersections between neighboring locally-approximately-linear arrays of threading dislocations consist essentially of three locally-approximately-linear arrays of threading dislocations meeting at intersection angles of 120°±3°. The first surface further comprises a plurality of second regions, each of the plurality of second regions being disposed between an adjacent pair of the plurality of first regions and having a concentration of threading dislocations below 10⁵ cm⁻² and a concentration of stacking faults below 10³ cm⁻¹. The first surface further comprises a plurality of third regions, each of the plurality of third regions being disposed within one of the plurality of second regions or between an adjacent pair of second and having a minimum dimension between 10 micrometers and 5 millimeters and threading dislocations with a concentration between 10₃ cm⁻² and 10⁸ cm⁻².

In some embodiments, the plurality of third regions comprise a two-dimensional pattern of third regions that comprises a repeating unit of third regions, wherein each repeating unit comprises: a portion of a first linear array of primary third regions, wherein the first linear array extends in the first direction; a portion of a second linear array of primary third regions, wherein the second linear array extends in the second direction; and a portion of a third linear array of two or more primary third regions, wherein the third linear array extends in the third direction, and the first linear array, the second linear array and the third linear array of the primary third regions cross at a plurality of intersection points. Each of the primary third regions can have a rectangular shape with a short dimension between about 3 micrometers and about 100 micrometers and a long dimension between about 200 micrometers and about 5 millimeters.

In some other embodiments, the plurality of third regions comprise: a two-dimensional array of primary third regions, wherein the primary third regions within the two-dimensional array have a rectangular shape with a short dimension between about 3 micrometers and about 100 micrometers and a long dimension between about 200 micrometers and about 5 millimeters. A first end of each of the primary third regions is positioned a first distance from a central point, and each primary third region is oriented so that a line that extends through the center of each primary third region and is parallel to the long dimension of the primary third region is not coincident with the central point.

Embodiments of the disclosure may provide a crystal, comprising a group III metal and nitrogen, wherein the crystal is free-standing and comprises a wurtzite crystal structure, a first surface having a maximum dimension greater than 5 millimeters in a first direction, the first surface having a crystallographic orientation within 5 degrees of one of (0001) and (000-1) and the first direction being aligned within ±3° of a crystallographic orientation selected from <10-10> and <11-20>, an average concentration of stacking faults below 10³ cm⁻¹, and an average concentration of threading dislocations between 10¹ cm⁻² and 10⁶ cm⁻², wherein the average concentration of threading dislocations on the first surface comprises periods of variation that vary periodically by at least a factor of two in each of the first direction, a second direction rotated by 60 degrees from the first direction, and third direction rotated by 120 degrees from the first direction, the periods of variation in the first direction, the second direction, and the third direction being equal, to within a factor of two, and each being between 5 micrometers and 20 millimeters. The first surface comprises a plurality of first regions, each of the plurality of first regions having a locally-approximately-linear array of threading dislocations with a concentration between 5 cm⁻¹ and 10⁵ cm⁻¹, and between 5% and 75% of intersections between neighboring locally-approximately-linear arrays of threading dislocations comprising three and only three locally-approximately-linear arrays of threading dislocations meeting at intersection angles of 120°±3°. The first surface further comprises a plurality of second regions, each of the plurality of second regions being at least partially disposed between an adjacent pair of the plurality of first regions and having a concentration of threading dislocations below 10⁵ cm⁻² and a concentration of stacking faults below 10³ cm⁻¹. The first surface further comprises a plurality of third regions, each of the plurality of third regions being disposed within one of the plurality of second regions or at least partially disposed between an adjacent pair of second regions and having a minimum dimension between 10 micrometers and 5 millimeters and threading dislocations with a concentration between 10³ cm⁻² and 10⁸ cm⁻².

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A, 1B, and 1C are simplified diagrams illustrating different stages of a method of forming a patterned photoresist layer on a seed crystal or a substrate, according to an embodiment of the present disclosure.

FIGS. 1D and 1E are simplified diagrams illustrating a method of forming a patterned mask layer on a seed crystal or a substrate, according to an embodiment of the present disclosure.

FIGS. 1F, 1G, 1H, 1I, and 1J are top views of arrangements of exposed regions in a patterned mask layer on a seed crystal or a substrate, according to an embodiment of the present disclosure.

FIGS. 1K and 1L are top views of arrangements of exposed regions in a patterned mask layer on a seed crystal or a substrate, according to an embodiment of the present disclosure.

FIGS. 1M and 1N are simplified diagrams illustrating different stages of a method of forming a patterned photoresist layer on a seed crystal or a substrate, according to an alternate embodiment of the present disclosure.

FIGS. 1O and 1P are simplified diagrams illustrating a method of forming a patterned mask layer on a seed crystal or a substrate, according to an alternate embodiment of the present disclosure.

FIG. 1Q is a simplified diagram illustrating a method of forming patterned trenches within a seed crystal or a substrate, according to an embodiment of the present disclosure.

FIGS. 1R, 1S, and 1T are simplified diagrams illustrating an alternative method of forming patterned trenches within a seed crystal or a substrate, according to an embodiment of the present invention.

FIGS. 2A, 2B, and 2C are simplified diagrams illustrating an epitaxial lateral overgrowth process for forming a large area group III metal nitride crystal, according to an embodiment of the present disclosure.

FIGS. 3A, 3B, and 3C are simplified diagrams illustrating an improved epitaxial lateral overgrowth process for forming a large area group III metal nitride crystal, according to an embodiment of the present disclosure.

FIGS. 3D, 3E, and 3F are simplified diagrams illustrating an improved epitaxial lateral overgrowth process for forming a large area group III metal nitride crystal, according to an embodiment of the present disclosure.

FIGS. 4A and 4B are simplified diagrams illustrating a method of forming a free-standing ammonothermal group III metal nitride boule and free-standing ammonothermal group III metal nitride wafers.

FIGS. 5A-5G are simplified diagrams illustrating threading dislocation patterns and regions on a free-standing ammonothermal group III metal nitride boule or wafer according to an embodiment of the present disclosure.

FIGS. 6 and 7A-7E are top views of arrangements of exposed regions in a patterned mask layer on a seed crystal or a substrate, according to an embodiment of the present disclosure.

FIGS. 8A-8E are simplified diagrams illustrating threading dislocation patterns and regions on a free-standing ammonothermal group III metal nitride boule or wafer according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the present disclosure, techniques related to techniques for processing materials for manufacture of group-III metal nitride and gallium based substrates are provided. More specifically, embodiments of the disclosure include techniques for growing large area substrates using a combination of processing techniques. Merely by way of example, the disclosure can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, laser diodes, light emitting diodes, photodiodes, solar cells, photo-electrochemical water splitting and hydrogen generation, photodetectors, integrated circuits, and transistors, and others.

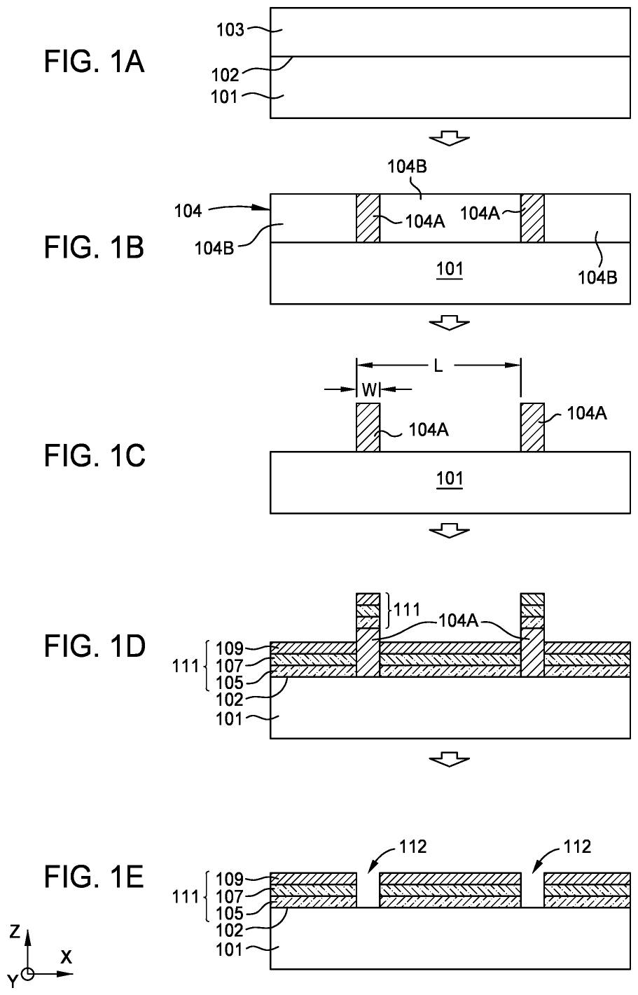

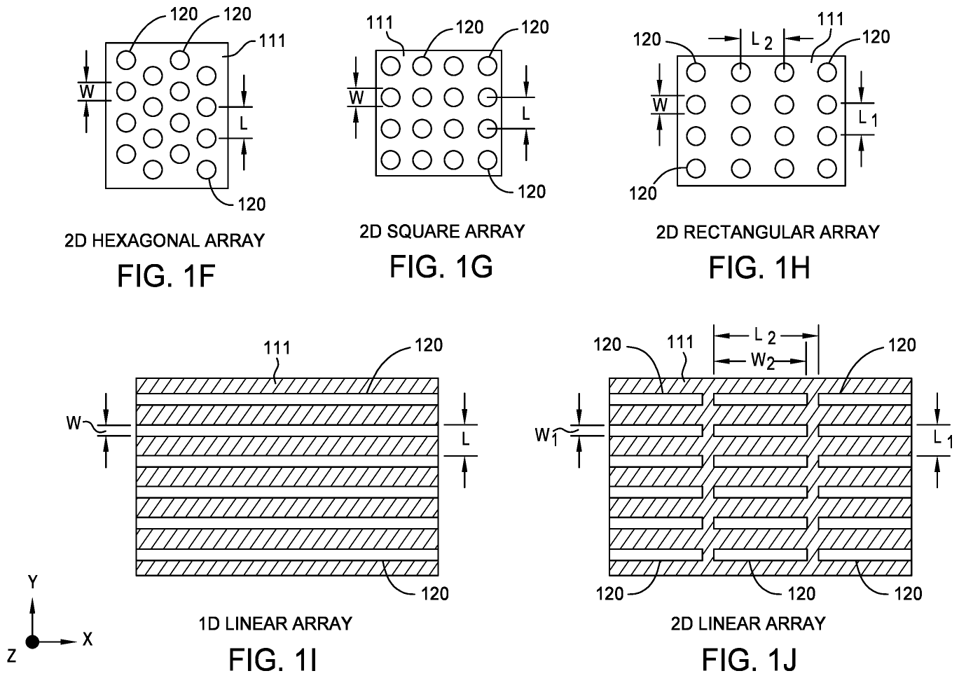

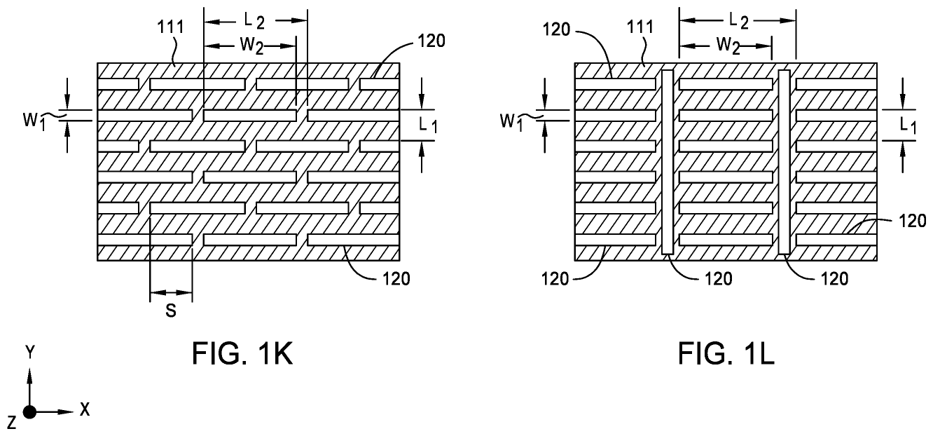

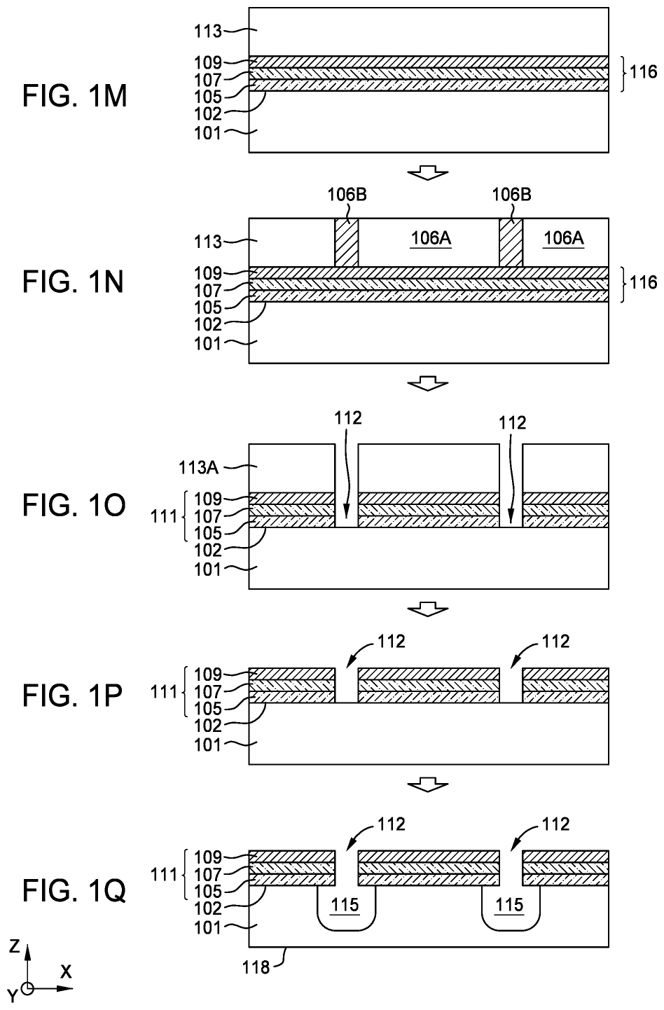

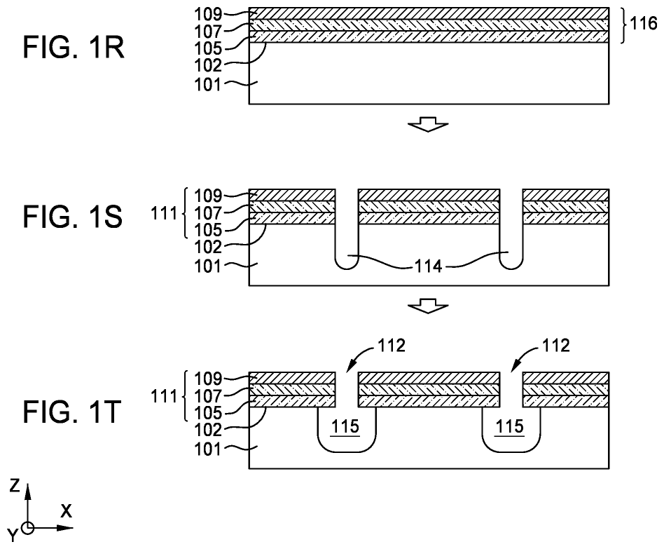

FIGS. 1A-1E are schematic cross-sectional views of a seed crystal or a substrate during various stages of a method for forming a patterned mask seed layer for ammonothermal sidewall lateral epitaxial overgrowth. Referring to FIG. 1A, a substrate 101 is provided with a photoresist layer 103 disposed thereon. In certain embodiments, substrate 101 consists of or includes a substrate material that is a single-crystalline group-III metal nitride, gallium-containing nitride, or gallium nitride. The substrate 101 may be grown by HVPE, ammonothermally, or by a flux method. One or both large area surfaces of substrate 101 may be polished and/or chemical-mechanically polished. A large-area surface 102 of substrate 101 may have a crystallographic orientation within 5 degrees, within 2 degrees, within 1 degree, or within 0.5 degree of (0001)+c-plane, (000−1)−c-plane, {10−⁺10} m-plane, {11−2±2}, {60−6±1}, {50−5±1}, {40−4±1}, {30−3±1}, {50−5±2}, {70−7±3}, {20−2±1}, {30−3±2}, {40−4±3}, {50−5±4}, {10−1±1}, {1 0−1±2}, {1 0−1±3}, {2 1−3±1}, or {3 0−3±4}. It will be understood that plane {3 0−3±4} means the {3 0−3 4} plane and the {3 0−3−4} plane. Large-area surface 102 may have an (h k i l) semipolar orientation, where i=−(h+k) and l and at least one of h and k are nonzero. Large-area surface 102 may have a maximum lateral dimension between about 5 millimeters and about 600 millimeters and a minimum lateral dimension between about 1 millimeter and about 600 millimeters and substrate 101 may have a thickness between about 10 micrometers and about 10 millimeters, or between about 100 micrometers and about 2 millimeters.

Substrate 101 may have a surface threading dislocation density less than about 10⁷ cm⁻², less than about 10⁶ cm⁻², less than about 10⁵ cm⁻², less than about 10⁴ cm⁻², less than about 10³ cm⁻², or less than about 10² cm⁻².

Large-area surface 102 (FIG. 1A) may have a crystallographic orientation within about 5 degrees of the (000-1) N-face, c-plane orientation, may have an x-ray diffraction ω-scan rocking curve full-width-at-half-maximum (FWHM) less than about 200 arcsec less than about 100 arcsec, less than about 50 arcsec, or less than about 30 arcsec for the (002) and/or the (102) reflections and may have a dislocation density less than about 10⁷ cm⁻², less than about 10⁶ cm⁻², or less than about 10⁵ cm⁻². In some embodiments, the threading dislocations in large-area surface 102 are approximately uniformly distributed. In other embodiments, the threading dislocations in large-area surface 102 are arranged inhomogenously as a one-dimensional array of rows of relatively high- and relatively low-concentration regions or as a two-dimensional array of high-dislocation-density regions within a matrix of low-dislocation-density regions. The crystallographic orientation of large-area surface 102 may be constant to less than about 5 degrees, less than about 2 degrees, less than about 1 degree, less than about 0.5 degree, less than about 0.2 degree, less than about 0.1 degree, or less than about 0.05 degree.

In certain embodiments, large-area surface 102 is roughened to enhance adhesion of a mask layer, for example, by wet-etching in at least a first etchant solution, to form a frosted morphology. In certain embodiments, wet-etching is performed in at least a first etchant solution, optionally followed by a second etchant solution. In certain embodiments, roughening is performed by etching in a solution of H₂O₂:NH₄OH in a ratio between about 1:3 and about 3:1 for a time between about 10 minutes and about 100 hours, at a temperature between about 15 degrees Celsius and about 50 degrees Celsius. In certain embodiments, roughening is performed by etching in a solution containing at least one of NaOH and KOH at a concentration between about 0.01 molar and about 5 molar at a temperature between about 15 degrees Celsius and about 95 degrees Celsius for a time between about 10 minutes and about 100 hours. In certain embodiments, at least one of the first etchant solution and the second etchant solution includes one or more of silicic acid hydrate, orthosilicic acid, boric acid, nitric acid, chlorosulfonic acid, sulfamic acid, nitrosylsulfuric acid, methanesulfonic acid, potassium carbonate, potassium bicarbonate, sodium carbonate, sodium bicarbonate, or the like. In certain embodiments, the roughening process includes or consists of a photochemical and/or photoelectrochemical process that includes above-bandgap illumination of surface 102. In certain embodiments, the roughened surface includes pyramidal, pyramid-like, and/or conical features. In certain embodiments, the roughened surface has a root-mean-square roughness between about 100 nanometers and about 500 micrometers, between about 1 micrometer and about 200 micrometers, or between about 10 micrometers and about 100 micrometers. In certain embodiments, the roughening treatment is performed after forming surface 102 by a wire-sawing method and/or by a grinding method. In certain embodiments, surface 102 has not been chemical-mechanically polished and has a root-mean-square roughness between about 1 micrometer and about 500 micrometers, or between about 10 micrometers and about 100 micrometers, prior to undergoing the roughening treatment. In certain embodiments, some smoothing of surface 102 occurs in conjunction with some roughening, for example, on different length scales or of different morphological features.

Referring again to FIG. 1A, a photoresist layer 103 may be deposited on the large-area surface 102 by methods that are known in the art. For example, in a certain embodiment of a lift-off process, a liquid solution of a negative photoresist is first applied to large-area surface 102. Substrate 101 is then spun at a high speed (for example, between 1000 to 6000 revolutions per minute for 30 to 60 seconds), resulting in a uniform photoresist layer 103 on large-area surface 102. Photoresist layer 103 may then be baked (for example, between about 90 and about 120 degrees Celsius) to remove excess photoresist solvent. After baking, the photoresist layer 103 may then be exposed to UV light through a photomask (not shown) to form a patterned photoresist layer 104 (FIG. 1B) having a pre-determined pattern of cross-linked photoresist, such as regions 104A, formed within the unexposed regions 104B. The regions 104B of the patterned photoresist may form stripes or dots having a characteristic width or diameter W and pitch L. The patterned photoresist layer 104 may then be developed to remove non-cross-linked material found in regions 1048 and leave regions 104A, such as illustrated in FIG. 1C.

Referring to FIG. 1D, one or more patterned mask layers 111 may be deposited on large-area surface 102 and regions 104A of the patterned photoresist layer 104. The one or more patterned mask layers 111 may comprise an adhesion layer 105 that is deposited on the large-area surface 102, a diffusion-barrier layer 107 deposited over the adhesion layer 105, and an inert layer 109 deposited over the diffusion-barrier layer 107.

In certain embodiments, the adhesion and cohesion strength of the patterned mask layers 111 is optimized by adjusting one or more process parameters. In certain embodiments, the adhesion strength of the patterned mask layers 111 is increased by rigorous cleaning of surface 102 before deposition. In certain embodiments, the rigorous cleaning includes one more of washing or sonication in one or more of deionized water, isopropyl alcohol, ethanol, acetone, 1-methyl-2-pyrrolidone, dimethyl sulfoxide, trichloroethylene, methylene chloride, Microposit™ remover 1165, another organic solvent, aqueous HCl, or another aqueous acid. In a specific embodiment, the adhesion and cohesion strength are increased by optimizing the pressure during a sputter deposition process of one or more of adhesion layer 105, diffusion-barrier layer 107, and inert layer 109. In certain embodiments, a sputter pressure is adjusted to control the level of stress in one or more coating, for example, by measuring induced bow on either the actual substrate 101 or on a test deposition surface. For example, the stress may be made more tensile by reducing the sputter-gas pressure, and more compressive by increasing the sputter-gas pressure. The stress may also be modified by changing an electrical bias present on substrate 101 during a sputter deposition process. In certain embodiments, the adhesion and/or cohesion strength of the patterned mask layers 111 are assessed using a pull-off test, such as one or more of ASTM D903 and D3359. In certain embodiments, the adhesion and/or cohesion strength of the pattern mask layers 111 are assessed by resistance to delamination during one or more of water washing, sonication in water, washing in aqueous HCl, and sonication in aqueous HCl, cleaving of the substrate and inspection of the fracture edges, and scratching surface 102 with a sharp tip.

FIGS. 1F-1L are top views of arrangements of exposed regions 120 on the substrate 101 formed by one or more of the processes described above. The exposed regions 120 (or also referred to herein as growth centers or primary growth centers), which are illustrated, for example, in FIGS. 1F-1L, may be defined by and/or include the openings 112 formed in patterned mask layer(s) 111 shown in FIG. 1E. In certain embodiments, the exposed regions 120 are arranged in a one-dimensional (1 D) array in the Y-direction, such as a single column of exposed regions 120 as shown in FIG. 1I. In certain embodiments, the exposed regions 120 are arranged in a two-dimensional (2D) array in X-direction and Y-directions, such as illustrated in FIGS. 1F-1H and 1J-1L. The openings 112, and thus exposed regions 120, may be round, square, rectangular, triangular, hexagonal, or the like, and may have an opening dimension W (or diameter W) between about 1 micrometer and about 5 millimeters, between about 3 micrometers and about 5 millimeters or between about 10 micrometers and about 500 micrometers such as illustrated in FIGS. 1F-1 L. The exposed regions 120 may be arranged in a 2D hexagonal or square array with a pitch dimension L between about 5 micrometers and about 20 millimeters, between about 200 micrometers and about 15 millimeters, or between about 500 micrometers and about 10 millimeters, or between about 0.8 millimeter and about 5 millimeters, such as illustrated in FIGS. 1F and 1G. The exposed regions 120 may be arranged in a 2D array, in which the pitch dimension L₁ in the Y-direction and pitch dimension L₂ in the X-direction may be different from one another, as illustrated in FIGS. 1H and 1J-1L. The exposed regions 120 may be arranged in a rectangular, parallelogram, hexagonal, or trapezoidal array (not shown), in which the pitch dimensions L₁ in the Y-direction and L₂ in the X-direction may be different from one another, as illustrated in FIGS. 1H and 1J-1L. The array of exposed regions 120 may also be linear or irregular shaped. The exposed regions 120 in patterned mask layer(s) 111 may be placed in registry with the structure of substrate 101. For example, in certain embodiments, large-area surface 102 has a hexagonal crystallographic orientation, e.g., a (0001) or (000-1) crystallographic orientation, and the openings in patterned mask layer(s) 111 comprise a 2D hexagonal array such that the separations between nearest-neighbor openings are parallel, to within ±5°, ±3°, ±2°, or ±1°, to <11-20> or <10-10> directions in large-area surface 102. In certain embodiments, large-area surface 102 of the substrate is nonpolar or semipolar and the exposed regions 120 comprise a 2D square or rectangular array such that the separations between nearest-neighbor openings are parallel to the projections of two of the c-axis, an m-axis, and an a-axis on large-area surface 102 of substrate 101. In certain embodiments, the pattern of exposed regions 120 is obliquely oriented with respect to the structure of substrate 101, for example, wherein the exposed regions 120 are rotated by between about 1 degree and about 44 degrees with respect to a high-symmetry axis of the substrate, such as a projection of the c-axis, an m-axis, or an a-axis on large-area surface 102 of substrate 101 that has a hexagonal crystal structure, such as a Wurtzite crystal structure. In certain embodiments, the exposed regions 120 are substantially linear rather than substantially round. In certain embodiments, the exposed regions 120 are slits having a width W and period L that run across the entire length of substrate 101, as illustrated in FIG. 1I. In certain embodiments, the exposed regions 120 are slits that have a width W₁ in the Y-direction and a predetermined length W₂ in the X-direction that is less than the length of substrate 101 and may be arranged in a 2D linear array with period L₁ in the Y-direction and period L₂ in the X-direction, as illustrated in FIGS. 1J-1L. In certain embodiments, the slits are oriented to within ±5°, ±3°, ±2°, or ±1° toward<11-20> or <10-10> directions in large-area surface 102. In some embodiments, adjacent rows of exposed regions 120 (e.g., slits) may be offset in the X-direction from one another rather than arranged directly adjacent, as shown in FIG. 1K. In a specific embodiment, exposed regions 120 include or consist of slits oriented to within ±3°, ±2°, or ±1° toward a <10-10> (X) direction and the separation between adjacent rows of slits in the y, or <11-20>, direction, L₁-W₁, is less than or equal to (W₂−½L₂)/\sqrt{3} and greater than or equal to (W₂−½L₂)/(3 \sqrt{3}) Put differently, the overlap s between exposed regions 120 in adjacent rows is greater than or equal to \sqrt{3}(L₁−W₁) and may be less than or equal to 3 \sqrt{3}(L₁−W₁). In this way, wings growing laterally from adjacent growth centers can coalesce after growth in a <11-20> direction only, with no <10-10> growth being required. In a specific embodiment, the axial separation between slits (L₂−W₂) is between about 5 micrometers and about 200 micrometers, or between about 10 micrometers and about 150 micrometers, or between about 25 micrometers and about 125 micrometers. In FIG. 1J the actual period of the array of exposed regions 120 in the X-direction is equal to the period L₂ between adjacent rows of exposed regions. The period in the X-direction is also equal to L₂ in FIG. 1K but the unit cell is a parallelogram rather than a rectangle as in FIG. 1J. In other embodiments, the actual period in the X-direction may be a multiple of L₂, for example, 2L₂, 3L₂, 4L₂, 5L₂, or 6L₂. In certain embodiments, the adjacent rows of exposed regions 120 (e.g., slits) may be offset in the longitudinal Y-direction from one another, as shown in FIG. 1K. In certain embodiments, the exposed regions 120 include slits that extend in two or more different directions, for example, the X-direction and the Y-direction, as shown in FIG. 1L. In certain embodiments, the exposed regions 120 (e.g., slits) may be arranged in a way that reflects the hexagonal symmetry of the substrate. In certain embodiments, the exposed regions 120 (e.g., slits) may extend to the edge of the substrate 101. In certain embodiments, surface 102 is masked by a rim adjacent to its edge, so that none of the exposed regions may extend to the edge of substrate 101. In certain embodiments, the masked rim has a width between about 25 micrometers and about 1 millimeter.

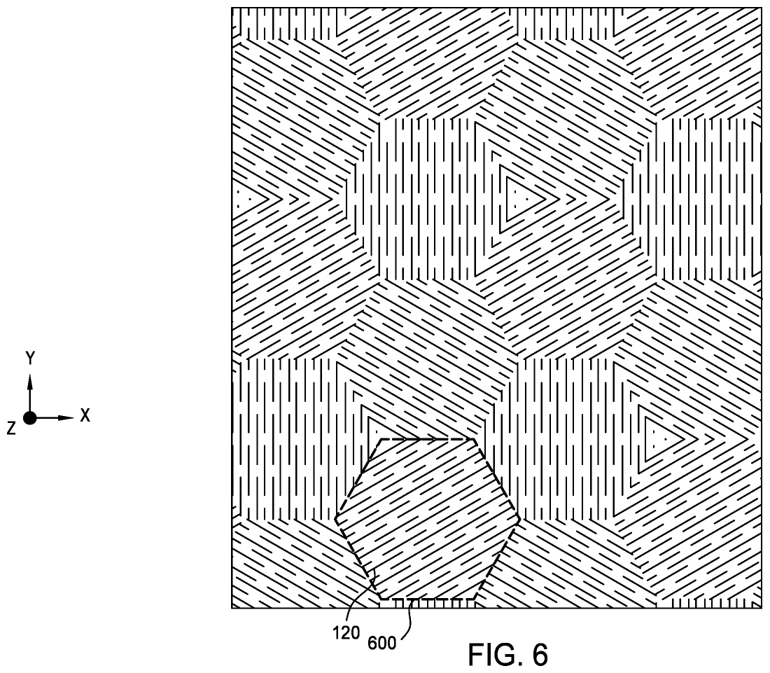

In certain embodiments, surface 102 has an orientation within about 10 degrees, within about 5 degrees, within about 2 degrees, within about 1 degree, or within about 0.5 degree of a (0001) or (000-1) c-plane. In certain embodiments, as shown schematically in FIG. 6, domains of patterns of exposed regions 120 each having a linear character, such as those shown schematically in FIGS. 1J and 1K, are arranged in a two-dimensional periodic tessellated array in three different orientations on surface 102. Each domain can include an array of exposed regions 120. As shown in FIG. 6, the surface 102 can include a tessellated array of hexagonal shaped domains 600 that include arrays of exposed regions 120, with adjacent domains being characterized by exposed regions 120 having a different orientation. In certain embodiments, approximately a third of each of the domains has exposed regions or growth centers, which may include or consist of slits, arranged within ±3°, ±2°, or ±1° toward [10−10], [01−10] and [−1100] directions. In certain embodiments, approximately a third of each of the domains has growth centers arranged within ±3°, ±2°, or ±1° toward [11−20], [1−210], and [−2110] directions. In certain embodiments, the domains have hexagonal boundaries, as illustrated schematically in FIG. 6. In certain embodiments, at least 90% of the domains having a first orientation are surrounded by six domains having alternating second and third orientations. In certain embodiments, the domains have a dimension in each of a first direction and a second, orthogonal direction, between about 500 micrometers and about 10 millimeters, or between about 1 millimeter and about 5 millimeters.

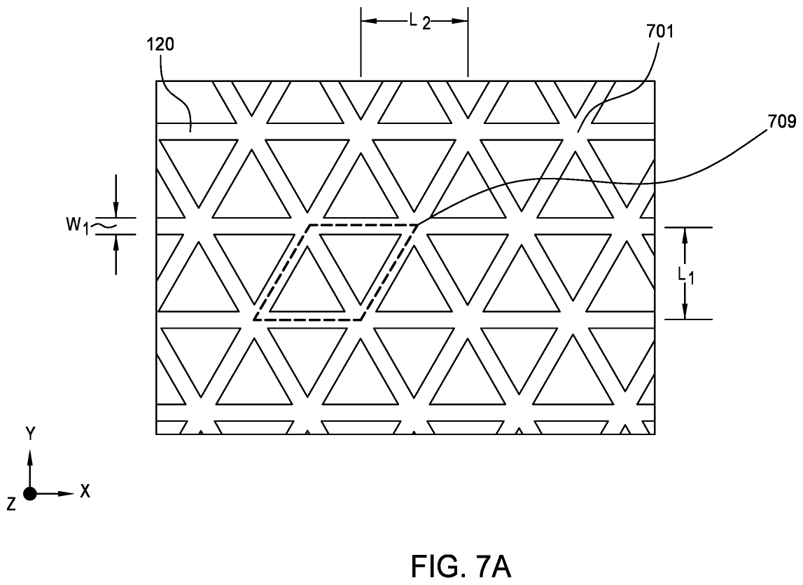

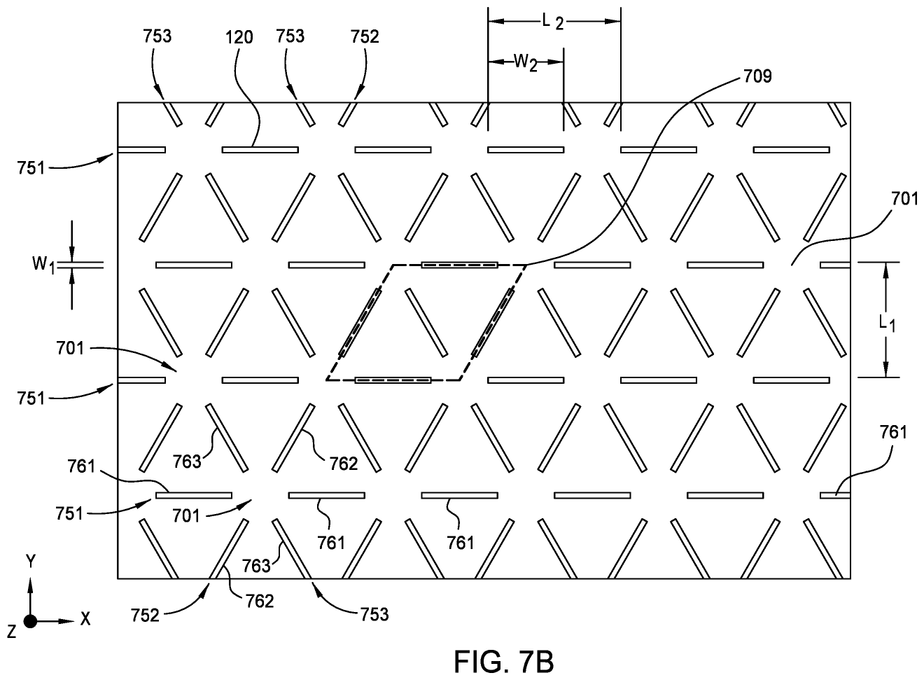

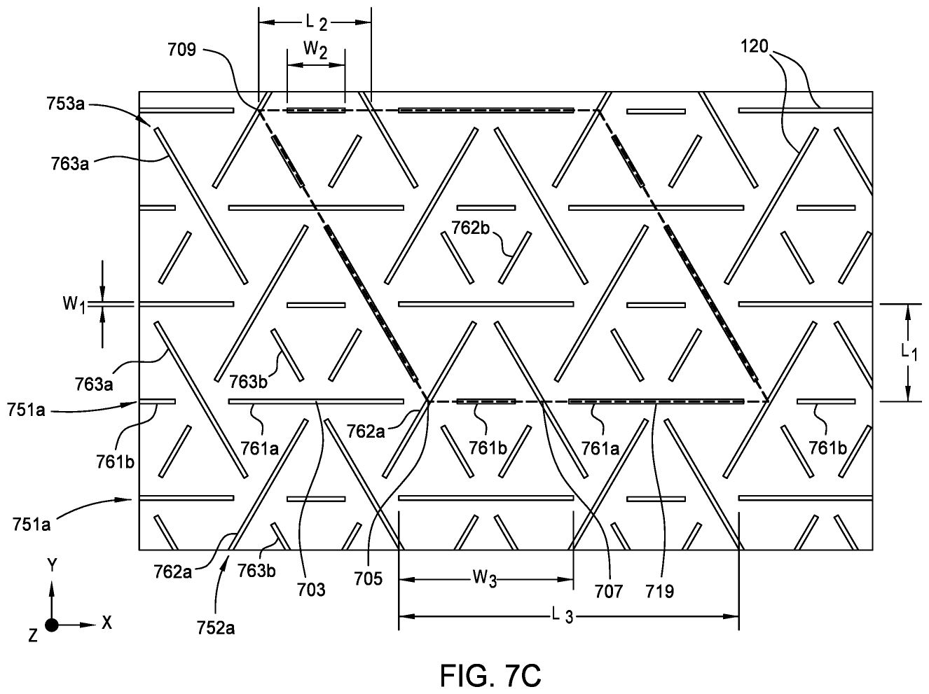

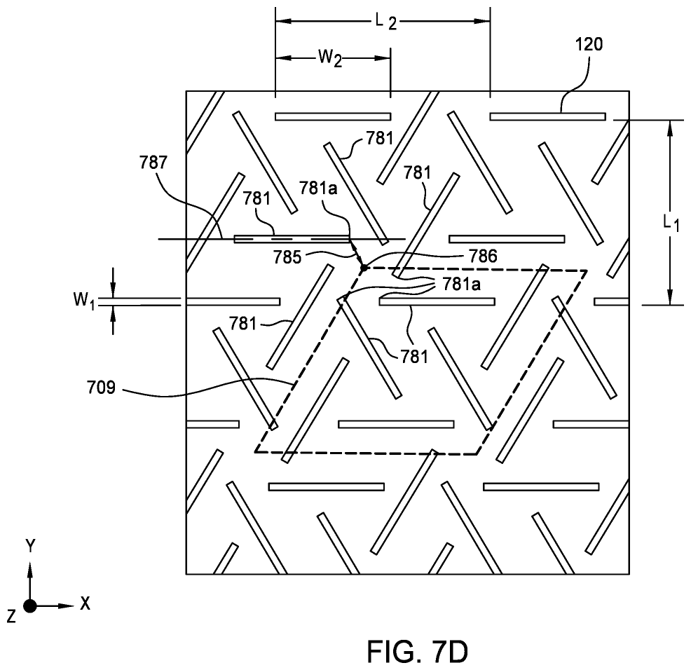

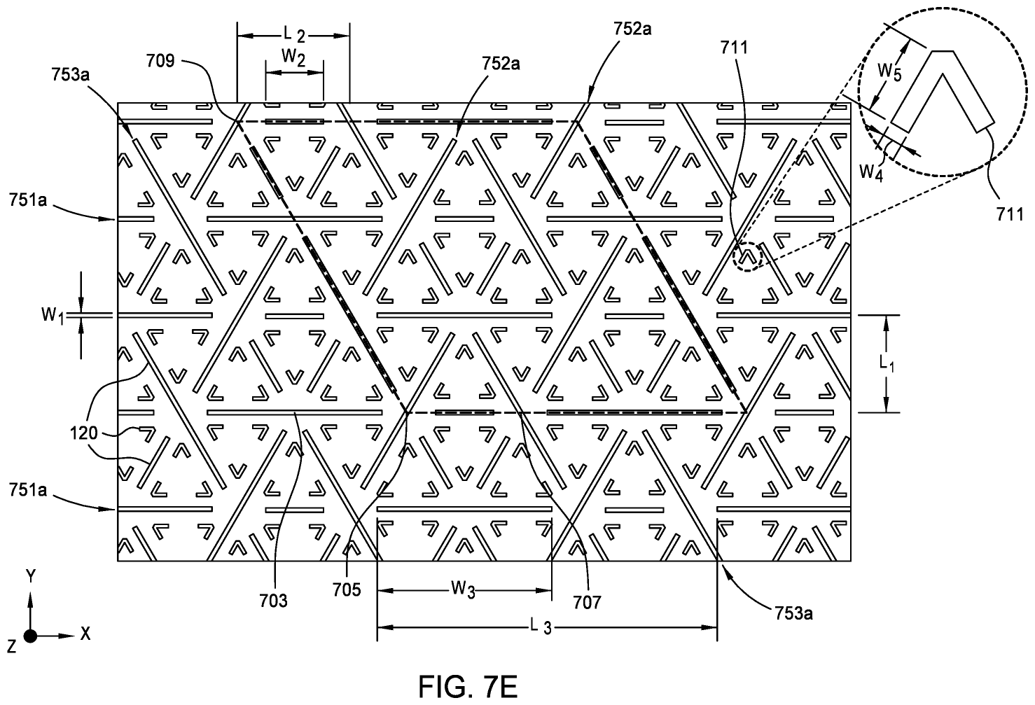

In certain embodiments, surface 102 has an orientation within about 10 degrees, within about 5 degrees, within about 2 degrees, within about 1 degree, or within about 0.5 degree of a (0001) or (000-1) c-plane. In certain embodiments, as shown schematically in FIG. 7A, growth centers (i.e., exposed regions 120), which as shown can include slits formed in a mask layer, are provided along each of three directions, rotated by 120 degrees from one another and having a common period L₂ along each of the three directions. In certain embodiments, approximately a third of each of the growth centers are arranged within ±3°, ±2°, or ±1° toward [10−10], [01−10] and [−1100] directions. In certain embodiments, approximately a third of each of the growth centers are arranged within ±3°, ±2°, or ±1° toward [11−20], [1−210], and [−2110] directions. In certain embodiments, the lengths of the growth centers are long in comparison to L₂, so that intersections 701 between three lines of growth centers are included within the growth centers. Intersections are also referred to herein as vertices and an intersection point is also referred to herein as a vertex. In certain embodiments, a primitive unit cell 709 for the pattern includes one and only one intersection 701, around which six growth centers are arranged with 60° angles between them. In certain embodiments, the growth centers extend to the edge of surface 102. In certain embodiments, the growth centers extend to a rim that is parallel to the edge of surface 102 and terminate there, where the rim has a width between about 25 micrometers and about 2 millimeters.

A possible disadvantage of having growth centers having a length that is comparable to a lateral dimension or diameter of substrate 102, as in FIG. 1I or 7A is that relaxation may occur only in laterally-grown material but not in the direction parallel to the growth centers. Interruptions in the growth centers, for example, as shown schematically in FIGS. 1J, 1K, and 1L, may enable relaxation in each of two orthogonal directions. Interruptions may similarly be introduced into the pattern shown schematically in FIG. 7A. In the pattern shown schematically in FIG. 7B, rather than intersections 701 being open, they are masked. The presence of masked intersections 701, with slit-shaped growth centers radiating from it, can cause slow coalescence above the intersections, as <10-10> direction growth may be required to cover them. In certain embodiments, a primitive unit cell 709 for the pattern includes one and only one intersection 701, around which six growth centers are arranged with 60° angles between them.

The pattern shown in FIG. 7B includes a plurality of linear arrays of growth centers that are formed in regular repeating patterns. In the example shown in FIG. 7B, the plurality of linear arrays of growth centers include a first linear array of growth centers 751, a second linear array of growth centers 752 and a third linear array of growth centers 753. The first linear array of growth centers 751 includes a plurality of growth centers 761 that are aligned in a first direction, such as the X-direction. The second linear array of growth centers 752 includes a plurality of growth centers 762 that are aligned in a second direction, which is aligned at an angle of 60 degrees from the first direction. The third linear array of growth centers 753 includes a plurality of growth centers 763 that are aligned in a third direction, which is aligned at an angle of 120 degrees from the first direction. The pattern shown in FIG. 7B also includes a plurality of intersections 701 (also referred to a vertices) that are formed at each of the points where the first linear array of growth centers, the second linear array of growth centers and the third linear array of growth centers cross in the formed repeating patterns. For clarity, intersections 701 refer to locations where lines, having a width equal to five times the width of the growth centers, passing through the centers of the first linear array of growth centers, the second linear array of growth centers, and the third linear array of growth centers, and oriented along the directions of the directions of the first linear array of growth centers, the second linear array of growth centers, and the third linear array of growth centers, respectively, intersect.

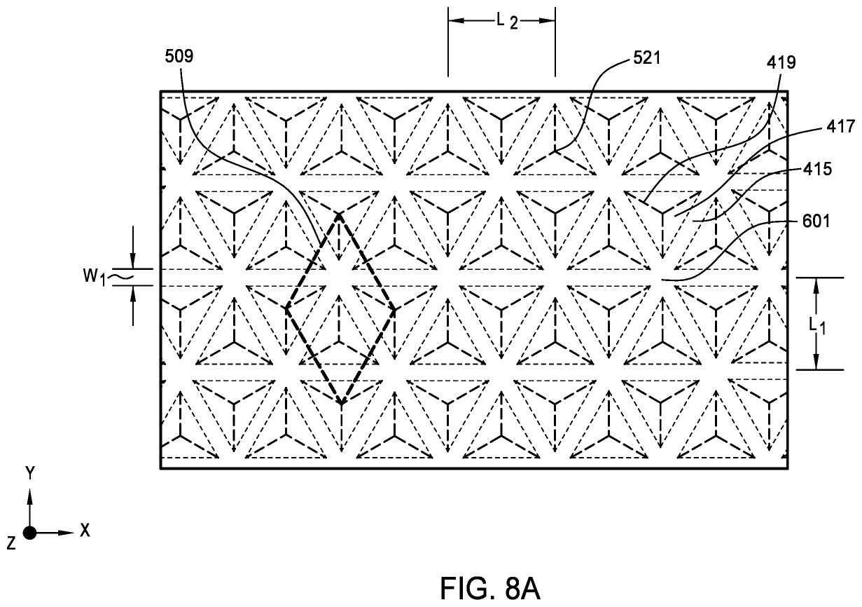

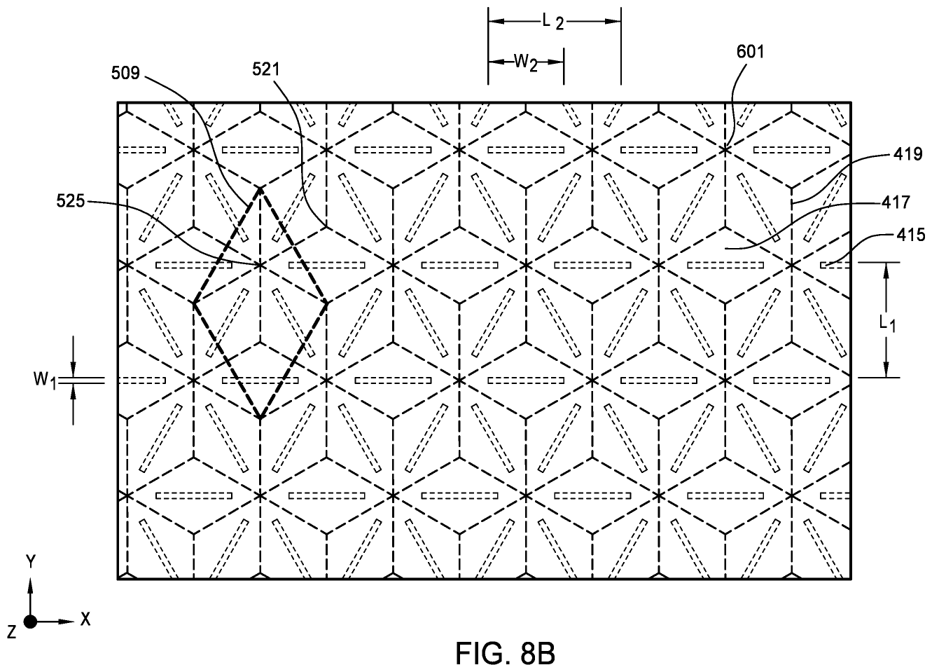

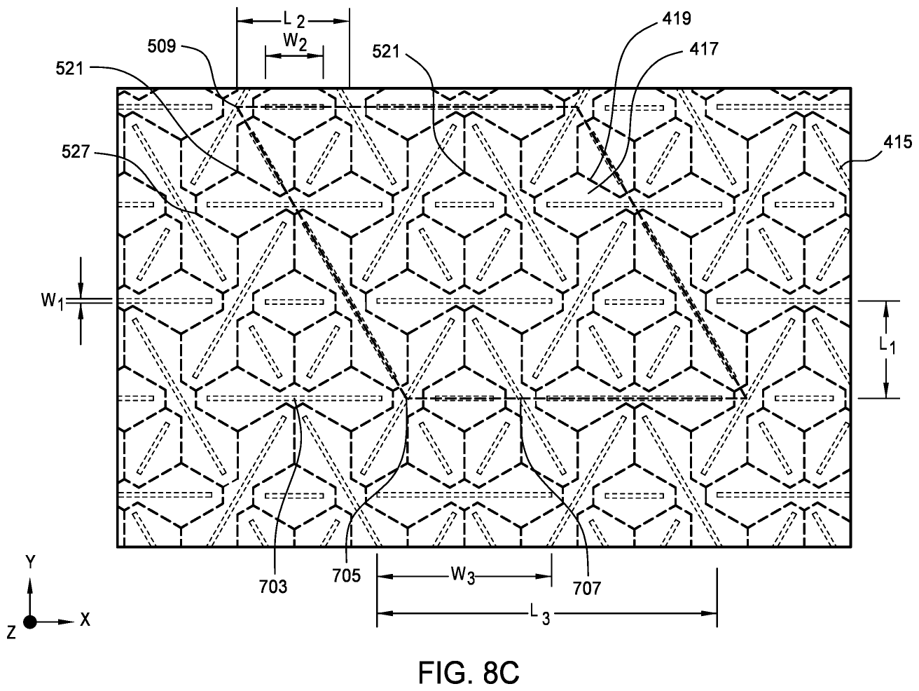

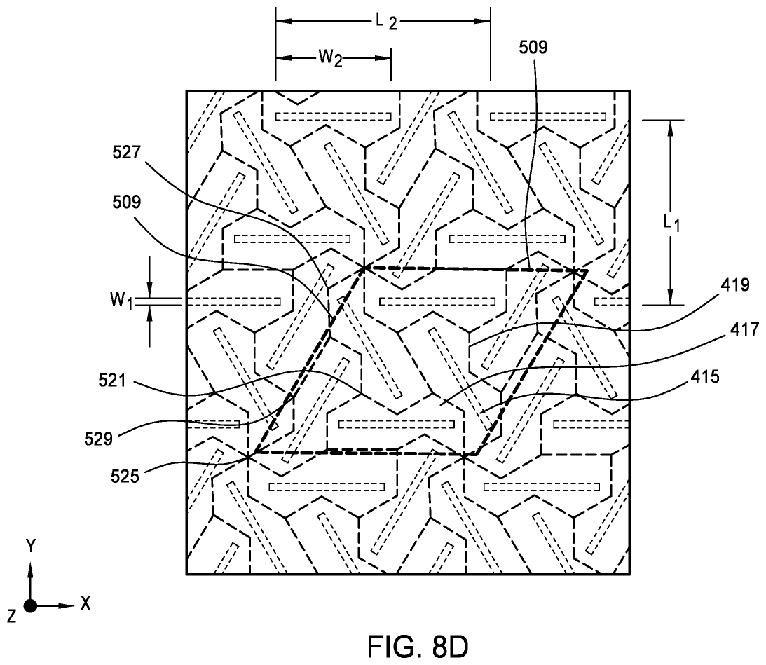

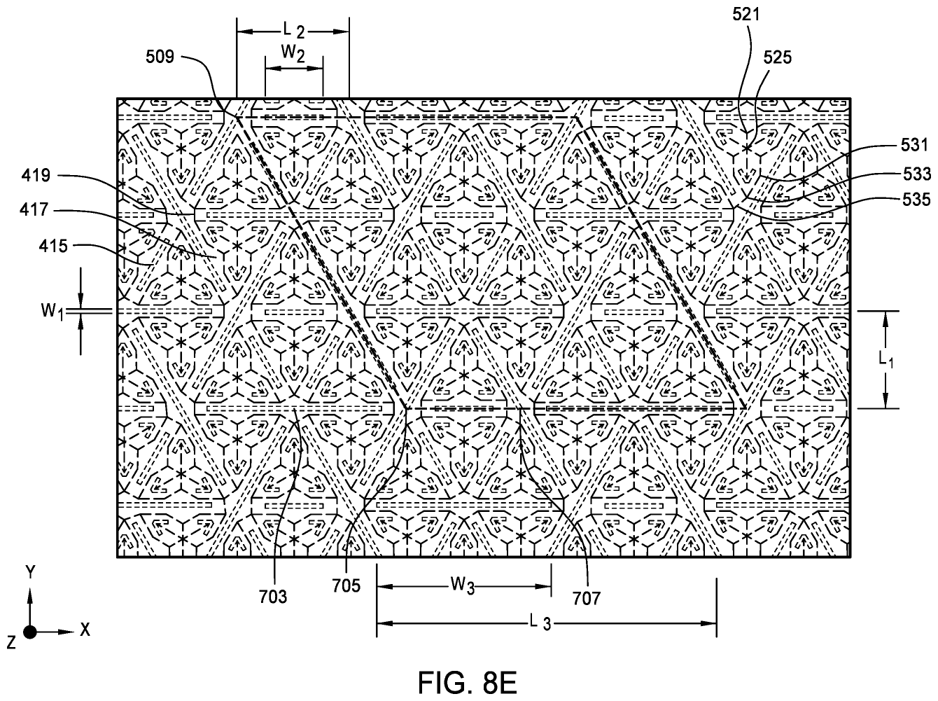

As will be discussed further below in relation to the examples shown in FIGS. 8A-8E, the portion of a crystal that grows vertically from the growth centers (e.g., exposed regions) within the pattern of linear arrays of growth centers form a plurality of primary window regions, or alternatively of primary third regions, which are oriented in the pattern of the linear arrays of growth centers from which they were grown.

In certain embodiments, as shown schematically in FIG. 7C, each vertex or intersection has a growth center of a single, specific orientation running through it. In a specific embodiment, adjacent intersections 703, 705, and 707 have slit-shaped growth centers oriented within ±3°, ±2°, or ±1° toward [10−10], [01−10] and [−1100] directions, respectively. In another specific embodiment, adjacent intersections 703, 705, and 707 have slit-shaped growth centers oriented within ±3°, ±2°, or ±1° toward [11−20], [1−210], and [−2110] directions, respectively. In the specific embodiment shown in FIG. 7C, the period in the X-direction L₃ is 3L₂, where L₂ is the separation between adjacent intersections in the X-direction, without regard to the type of intersection point. In certain embodiments, the period in the X-direction, and in each of two directions rotated by 120 degrees with respect to the X-direction, is equal to at least one of L₂, 2L₂, 3 L₂, 4 L₂, 5 L₂, 6L₂, or a larger multiple of L₂. In certain embodiments, the period in the Y-direction, and in each of two directions rotated by 120 degrees with respect to the Y-direction, is equal to at least one of L₁, 2L₁, 3L₁, 4L₁, 5L₁, 6L₁, or a larger multiple of L₁. The growth centers may have a width W₁. Short growth centers, which do not extend through the vertices, may have a length W₂. Long growth centers, which may extend through one and only one intersection, may have a length W₃. In certain embodiments, a primitive unit cell 709 for the pattern includes nine and only nine vertices, including three each of types of adjacent intersections 703, 705 and 707, around which six growth centers are arranged with 60° angles between them.

The pattern shown in FIG. 7C includes a plurality of linear arrays of growth centers that are formed in an alternate regular repeating pattern of growth centers. In the example shown in FIG. 7C, the plurality of linear arrays of growth centers include a first linear array of growth centers 751a, a second linear array of growth centers 752a and a third linear array of growth centers 753a. In the example shown in FIG. 7C, the first, second and third linear arrays of growth centers include two different types of growth centers, such as a long growth center 761a, 762a, 763a and a short growth center 761b, 762b, 763b, respectively, that are each aligned in their respective linear array direction. Each of the linear arrays of growth centers include at least one growth center (e.g., long growth center 761a, 762a, 763a) that extends through every third intersection 701 taken in the direction that the linear array of growth centers extend. For example, the first linear array of growth centers 751a includes a plurality of growth centers 761a and 761b, and the growth centers 761a extend through a first intersection 703 and a fourth intersection 719 as the first linear array of growth centers extend in the first direction (e.g., X-direction). The long growth centers 761a, 762a, 763a positioned in a linear sequence of the intersections 701, such as intersections 703, 705, and 707 in FIG. 7C, include intersections where the long growth centers 761a, 762a, 763a sequentially extend through the center of the intersection and are oriented in the first direction, the second direction, and the third direction, respectively.

In certain embodiments, rows of growth centers from a configuration like that shown schematically in FIG. 7B are displaced to avoid intersections 701 to which multiple neighboring growth centers point. An example of these embodiments is shown schematically in FIG. 7D. In certain embodiments, approximately a third of each of the growth centers are oriented within ±3°, ±2°, or ±1° toward [10−10], [01−10] and [−1100] directions. In certain embodiments, approximately a third of each of the growth centers are oriented within ±3°, ±2°, or ±1° toward [11−20], [1−210], and [−2110] directions. In certain embodiments, one end of each of the growth centers points toward a central portion of a neighboring growth center or slit and the other end points toward an end portion of a neighboring growth center or slit. In certain embodiments, the period L₁ is the same in each of three orientations, for example, in the Y-direction and in directions rotated by ±120° with respect to the Y-direction. In certain embodiments, at least six growth centers are included within primitive unit cell 709. In certain embodiments, precisely six growth centers are included within primitive unit cell 709.

The pattern shown in FIG. 7D includes a plurality of linear arrays of growth centers that are formed in an alternate regular repeating pattern of growth centers. In this example, the plurality of linear arrays of growth centers are formed in a two-dimensional array of growth centers, wherein the growth centers 781 within the two-dimensional array have a rectangular shape with a short dimension and a long dimension, and a first end 781a of each of the growth centers 781 is positioned a first distance 785 from a central point 786, and each growth center is oriented so that a line 787 (only one shown) that extends through a center of each growth center 781 and is parallel to the long dimension of the growth center is not coincident with the central point 786.

The pattern shown in FIG. 7E includes a plurality of linear arrays of growth centers that are formed in a regular repeating pattern of growth centers that also include a plurality of secondary openings. In one example, the pattern shown in FIG. 7E includes a plurality of linear arrays of primary growth centers that are configured similarly to the configuration shown in FIG. 7C, and also includes a plurality of second openings 711. In some cases, it has been found that, depending on the pitch of the pattern (e.g., L₁ and L₂) and the growth conditions, coalescence may be slower than desired. In some embodiments, as shown in FIG. 7E, secondary openings 711 (or secondary growth centers), or additional growth centers, may be included within a larger pattern that consists or includes primary growth centers, for example, within triangular-shaped features, as shown schematically in FIG. 7E. In certain embodiments, the secondary openings 711 are round, square, rectangular, triangular, hexagonal, or the like. In certain embodiments, the secondary openings 711 include or consist of slit-shaped features. In certain embodiments, slits within the secondary openings 711 are oriented within ±3°, ±2°, or ±1° toward [10−10], [01−10] and/or [−1100] directions. In certain embodiments, slits within the secondary openings 609 are oriented within ±3°, ±2°, or ±1° toward [11−20], [1−210], and [−2110] directions. In certain embodiments, as shown schematically in FIG. 7E, secondary openings 711 have a chevron shape and are positioned within triangular-shaped regions of the pattern. In certain embodiments, secondary openings 711 include two intersecting slit-shaped features that are oriented at an angle to each other. In certain embodiments, secondary openings 711 include two slit-shaped features that meet at one end with an angle of approximately 60 degrees, for example, between about 55 degrees and about 65 degrees. The width W₄ of the secondary openings 711 may be similar to, or less than, the width W₁ of the primary openings. In certain embodiments, the ratio of the length W₅ of the secondary openings to the length W₂ of the short primary openings is between about 0.9 and about 0.01, or between about 0.5 and about 0.05, or between about 0.3 and about 0.1. In certain embodiments, at least 3, at least 9, at least 18, at least 27, or at least 50 secondary openings 711 are included within primitive cell 709 that is defined by the primary openings.

In an alternative set of embodiments, as shown in FIG. 1M, large-area surface 102 of substrate 101 is covered with a blanket mask 116, comprising one, two, or more of adhesion layer 105, diffusion-barrier layer 107, and inert layer 109, followed by a positive photoresist layer 113. The photoresist layer is exposed to UV light through a photomask (not shown), forming solubilizable, exposed regions 106B and unexposed regions 106A, as shown in FIG. 1N (essentially the negative of the pattern shown in FIG. 1B). Exposed regions 106B are then removed by developing. As shown in FIG. 1O, openings 112 in the blanket mask 116 (comprising adhesion layer 105, diffusion-barrier layer 107, and inert layer 109) may then be formed by wet or dry etching through the openings in patterned photoresist layer 113A, to form the patterned mask layer 111. After forming the openings 112 the photoresist layer 113 is removed, as shown in FIG. 1P, producing a structure that is similar or identical to that shown in FIG. 1E.

Trenches 115 are then formed in exposed regions 120 of the substrate 101 through the openings 112 (or “windows”) formed in patterned mask layer 111, as shown in FIG. 1Q. In certain embodiments, the depth of the trenches 115 is between 50 micrometers and about 1 millimeter or between about 100 micrometers and about 300 micrometers. In certain embodiments the trenches 115 penetrate the entire thickness of substrate 101, forming patterned holes that extend from the rear side 118 of the substrate 101 and through the openings 112 of the patterned mask layer 111. The width of an individual trench may be between about 10 micrometers and about 500 micrometers, or between about 20 micrometers and about 200 micrometers. Individual trenches 115 may be linear or curved and may have a length in the X-direction and/or Y-direction between about 100 micrometers and about 50 millimeters, or between about 200 micrometers and about 10 millimeters, or between about 500 micrometers and about 5 millimeters. In a specific embodiment, large-area surface 102 of substrate 101 has a (000-1), N-face orientation and trench 115 is formed by wet etching. In a specific embodiment, an etchant composition or solution comprises a solution of 85% phosphoric acid (H₃PO₄) and sulfuric (H₂SO₄) acids with a H₂SO₄/H₃PO₄ ratio between 0 and about 1:1. In certain embodiments, a phosphoric acid solution is conditioned to form polyphosphoric acid, increasing its boiling point. For example, reagent-grade (85%) H₃PO₄ may be conditioned by stirring and heating in a beaker at a temperature between about 200 degrees Celsius and about 450 degrees Celsius for between about 5 minutes and about five hours. In a specific embodiment, trench 115 is formed by heating masked substrate 101 in one of the aforementioned etch solutions at a temperature between about 200 degrees Celsius and about 350 degrees Celsius for a time between about 15 minutes and about 6 hours. In another embodiment, trench 115 is formed by electrochemical wet etching.

FIGS. 1R-1T show an alternative approach to forming an array of patterned, masked trenches in substrate 101. A blanket mask 116 (comprising adhesion layer 105, diffusion-barrier layer 107, and inert layer 109) may be deposited on large-area surface 102 of substrate 101 as shown in FIG. 1R. Nascent trenches 114 may be formed by laser ablation, as shown in FIG. 1S, to form a patterned mask layer 111. The laser ablation process is also known as or referred to as laser machining or laser beam machining processes. Laser ablation may be performed by a watt-level laser, such as a neodymium-doped yttrium-aluminum-garnet (Nd:YAG) laser, a CO₂ laser, an excimer laser, a Ti:sapphire laser, or the like. The laser may emit pulses with a pulse length in the nanosecond, picosecond, or femtosecond range. In certain embodiments the frequency of the output light of the laser may be doubled, tripled, or quadrupled using an appropriate nonlinear optic. The beam width, power, and scan rate of the laser over the surface of substrate 101 with patterned mask layer 111 may be varied to adjust the width, depth, and aspect ratio of nascent trenches 114. The laser may be scanned repetitively over a single trench or repetitively over the whole array of trenches.

The surfaces and sidewalls of the nascent trenches 114 may contain damage left over from the laser ablation process. In certain embodiments, substrate 101, containing nascent trenches 114, is further processed by wet etching, dry etching, or photoelectrochemical etching in order to remove residual damage in nascent trenches 114 as shown in FIG. 1T. In a specific embodiment, large-area surface 102 of substrate 101 has a (000-1), N-face orientation and a trench 115 is formed from nascent trench 114 by wet etching. In a specific embodiment, an etchant composition or solution comprises a solution of 85% phosphoric acid (H₃PO₄) and sulfuric (H₂SO₄) acids with a H₂SO₄/H₃PO₄ ratio between 0 and about 1:1. In certain embodiments, a phosphoric acid solution is conditioned to form polyphosphoric acid, increasing its boiling point. For example, reagent-grade (85%) H₃PO₄ may be conditioned by stirring and heating in a beaker at a temperature between about 200 degrees Celsius and about 450 degrees Celsius for between about 5 minutes and about five hours. In a specific embodiment, trench 115 is formed by heating substrate 101 in one of the aforementioned etch solutions at a temperature between about 200 degrees Celsius and about 350 degrees Celsius for a time between about 15 minutes and about 6 hours.

The patterns in the mask layer below which trenches 115 are formed may be chosen from, for example, any of the patterns described above, such as those shown schematically in FIG. 1F-1L, 6, or 7A-7E.

The substrate 101 with patterned mask layers and, optionally, the masked, patterned trenches 115, is then used as a substrate for bulk crystal growth, for example, comprising ammonothermal growth, HVPE growth, or flux growth. In the discussion below the grown GaN layer will be referred to as an ammonothermal layer, even though other bulk growth methods, such as HVPE or flux growth, may be used instead. In certain embodiments, comprising ammonothermal bulk growth, patterned substrate 101 may then be suspended on a seed rack and placed in a sealable container, such as a capsule, an autoclave, or a liner within an autoclave. In certain embodiments, one or more pairs of patterned substrates are suspended back-to-back, with the patterned large area surfaces facing outward. A group III metal source, such as polycrystalline group III metal nitride, at least one mineralizer composition, and ammonia (or other nitrogen containing solvent) are then added to the sealable container and the sealable container is sealed. The mineralizer composition may comprise an alkali metal such as Li, Na, K, Rb, or Cs, an alkaline earth metal, such as Mg, Ca, Sr, or Ba, or an alkali or alkaline earth hydride, amide, imide, amido-imide, nitride, or azide. The mineralizer may comprise an ammonium halide, such as NH₄F, NH₄Cl, NH₄Br, or NH₄I, a gallium halide, such as GaF₃, GaCl₃, GaBr₃, Gals, or any compound that may be formed by reaction of one or more of F, Cl, Br, I, HF, HCl, HBr, HI, Ga, GaN, and NH₃. The mineralizer may comprise other alkali, alkaline earth, or ammonium salts, other halides, urea, sulfur or a sulfide salt, or phosphorus or a phosphorus-containing salt. The sealable container (e.g., capsule) may then be placed in a high pressure apparatus, such as an internally heated high pressure apparatus or an autoclave, and the high pressure apparatus sealed. The sealable container, containing patterned substrate 101, is then heated to a temperature above about 400 degrees Celsius and pressurized above about 50 megapascal to perform ammonothermal crystal growth.

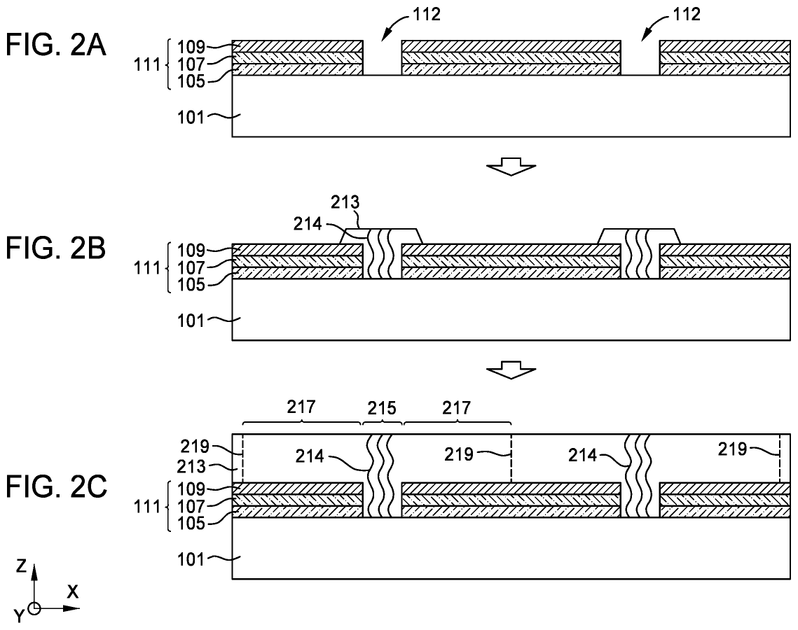

FIGS. 2A-2C illustrate bulk crystal growth by a conventional LEO process with no trenches below mask openings. During a bulk crystal growth process, group III metal nitride layer 213 grows through the openings 112 of patterned mask layer 111, grows outward through the openings, as shown in FIG. 2B, grows laterally over patterned mask layer 111, and coalesces, as shown in FIG. 2C. After coalescence, group III metal nitride layer 213 comprises window regions 215, which have grown vertically with respect to the openings in patterned mask layer 111, wing regions 217, which have grown laterally over patterned mask layer 111, and coalescence fronts 219, which form at the boundaries between wings growing from adjacent openings in patterned mask layer 111. Threading dislocations 214 may be present in window regions 215, originating from threading dislocations that were present at the surface of the substrate 101.

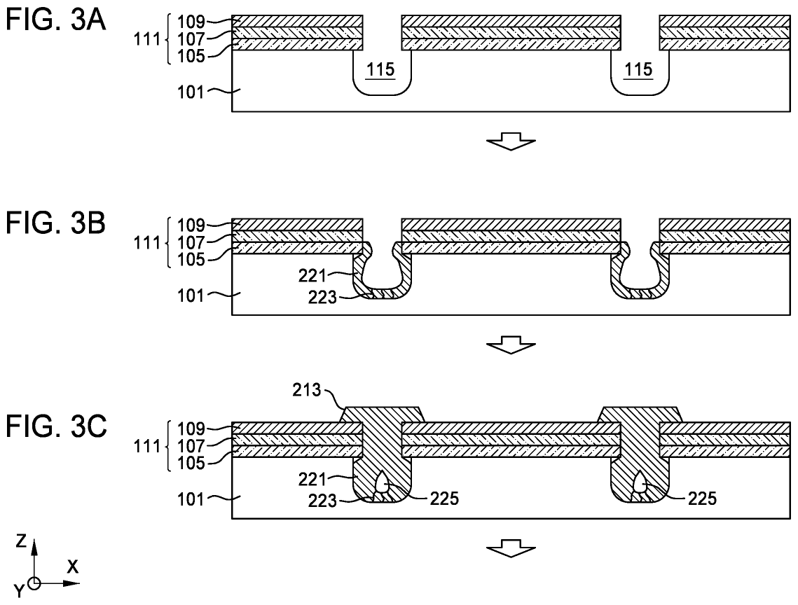

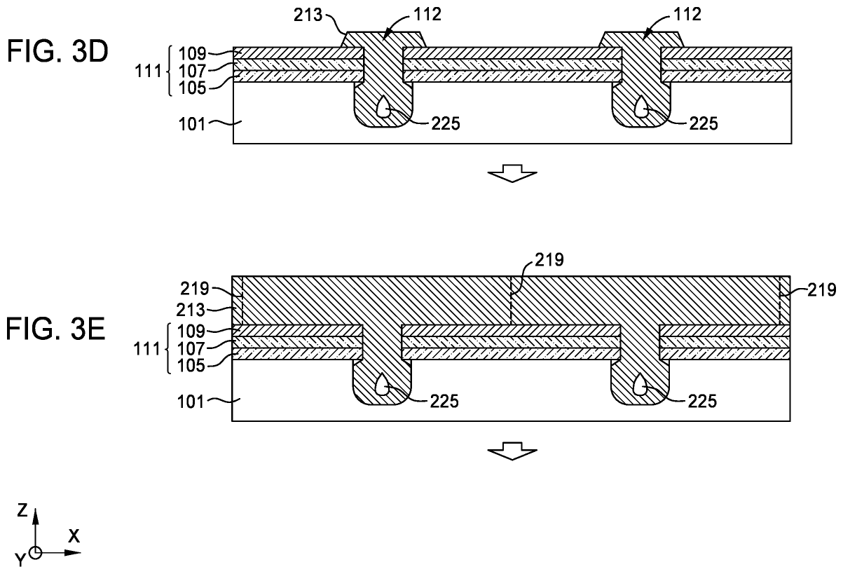

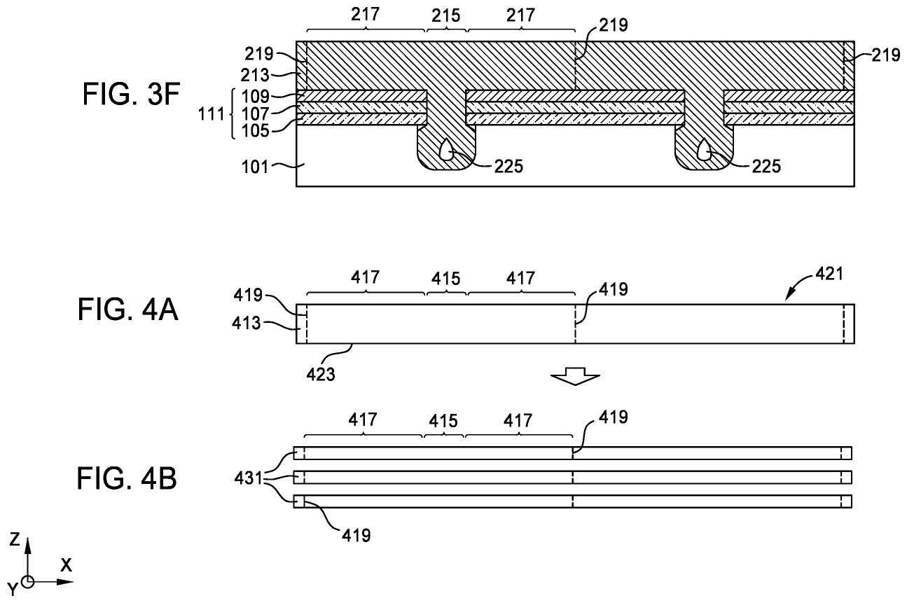

FIGS. 3A-3C illustrate a bulk group III nitride sidewall LEO process. FIG. 3A illustrates a substrate that includes a patterned, masked trench 115, formed by one of the processes described herein. In a sidewall LEO process, a group III metal nitride material 221 grows on the sides and bottoms of the patterned, masked trenches 115 as shown in FIG. 3B. As group III metal nitride material 221 on the sidewalls of trenches 115 grow inward, it becomes progressively more difficult for group III nitride nutrient material to reach the bottom of the trenches, whether the nutrient material comprises an ammonothermal complex of a group III metal (in the case of ammonothermal growth), a group III metal halide (in the case of HVPE), or a group III metal alloy or inorganic complex (in the case of flux growth). Eventually group III metal nitride material 221 pinches off the lower regions of the trenches, forming voids 225 as shown in FIG. 3C. It has been found that the concentration of threading dislocations in the group III metal nitride material 221, which has grown laterally, is lower than that in substrate 101. Many threading dislocations 223, originating from substrate 101, terminate on the surfaces of voids 225. Concomitantly, the group III metal nitride layer 213 grows upward through openings 112 (or windows) in patterned mask layer 111. However, since laterally-grown group III metal nitride material 221 has a lower concentration of threading dislocations than substrate 101 and many dislocations from substrate 101 have terminated at surfaces of voids 225, the dislocation density in the vertically grown group III metal nitride layer 213 is considerably reduced, relative to a conventional LEO process, as described above in conjunction with FIG. 2A-2C.

FIGS. 3D-3F illustrate the continuation of the sidewall LEO growth process. As in the conventional LEO process (FIGS. 2A-2C), group III metal nitride layer 213 grows within the openings 112 of patterned mask layer 111, grows outward through the openings as shown in FIG. 3D, grows laterally over patterned mask layer 111, and coalesces, as shown in FIG. 3E. After coalescence, group III metal nitride layer 213 comprises window regions 215, which have grown vertically with respect to the openings in patterned mask layer 111, wing regions 217, which have grown laterally over patterned mask layer 111, and coalescence fronts 219, which form at the boundaries between wings growing from adjacent openings in patterned mask layer 111, as shown in FIG. 3F. Since laterally-grown group III metal nitride material 221 has a lower concentration of threading dislocations than substrate 101 and many threading dislocations from substrate 101 have terminated in voids 225, the concentration of threading dislocations in window regions 215 is significantly lower than in the case of conventional LEO.

Ammonothermal group III metal nitride layer 213 may have a thickness between about 10 micrometers and about 100 millimeters, or between about 100 micrometers and about 20 millimeters.

In certain embodiments, ammonothermal group III metal nitride layer 213 is subjected to one or more processes, such as at least one of sawing, lapping, grinding, polishing, chemical-mechanical polishing, or etching.

In certain embodiments, the concentration of extended defects, such as threading dislocations and stacking faults, in the ammonothermal group III metal nitride layer 213 may be quantified by defect selective etching. Defect-selective etching may be performed, for example, using a solution comprising one or more of H₃PO₄, H₃PO₄ that has been conditioned by prolonged heat treatment to form polyphosphoric acid, and H₂SO₄, or a molten flux comprising one or more of NaOH and KOH. Defect-selective etching may be performed at a temperature between about 100 degrees Celsius and about 500 degrees Celsius for a time between about 5 minutes and about 5 hours, wherein the processing temperature and time are selected so as to cause formation of etch pits with diameters between about 1 micrometer and about 25 micrometers, then removing the ammonothermal group III metal nitride layer, crystal, or wafer from the etchant solution.

The concentration of threading dislocations in the surface of the window regions 215 may be less than that in the underlying substrate 101 by a factor between about 10 and about 10⁴. The concentration of threading dislocations in the surface of the window regions 215 may be less than about 10⁸ cm⁻², less than about 10⁷ cm⁻², less than about 10⁶ cm⁻², less than about 10⁵ cm⁻², or less than about 10⁴ cm⁻². The concentration of threading dislocations in the surface of wing regions 217 may be lower, by about one to about three orders of magnitude, than the concentration of threading dislocations in the surface of the window regions 215, and may be below about 10⁵ cm⁻², below about 10⁴ cm⁻², below about 10³ cm⁻², below about 10² cm⁻², or below about 10 cm⁻². Some stacking faults, for example, at a concentration between about 1 cm⁻¹ and about 10⁴ cm⁻¹, may be present at the surface of the window regions 215. The concentration of stacking faults in the surface of wing regions 217 may be lower, by about one to about three orders of magnitude, than the concentration of stacking faults in the surface of the window regions 215, and may be below about 10² cm⁻¹, below about 10 cm⁻¹, below about 1 cm⁻¹, or below about 0.1 cm⁻¹, or may be undetectable. Threading dislocations, for example, edge dislocations, may be present at coalescence fronts 219, for example, with a line density that is less than about 1×10⁵ cm⁻¹, less than about 3×10⁴ cm⁻¹, less than about 1×10⁴ cm⁻¹, less than about 3×10³ cm⁻¹, less than about 1×10³ cm⁻¹, less than about 3×10² cm⁻¹, or less than 1×10² cm⁻¹. The density of dislocations along the coalescence fronts may be greater than 5 cm⁻¹, greater than 10 cm⁻¹, greater than 20 cm⁻¹, greater than 50 cm⁻¹, greater than 100 cm⁻¹, greater than 200 cm⁻¹, or greater than 500 cm⁻¹.

In certain embodiments, the process of masking and bulk group III nitride crystal growth is repeated one, two, three, or more times. In some embodiments, these operations are performed while the first bulk group III metal nitride layer remains coupled to substrate 101. In other embodiments, substrate 101 is removed prior to a subsequent masking and bulk crystal growth operation, for example, by sawing, lapping, grinding, and/or etching.

FIGS. 4A and 4B are simplified diagrams illustrating a method of forming a free-standing group III metal nitride boule and free-standing group III metal nitride wafers. In certain embodiments, substrate 101 is removed from ammonothermal group III metal nitride layer 213 (FIG. 3F), or the last such layer deposited, to form free-standing ammonothermal group III metal nitride boule 413. Removal of substrate 101 may be accomplished by one or more of sawing, grinding, lapping, polishing, laser lift-off, self-separation, and etching to form a processed free-standing laterally-grown group III metal nitride boule 413. The processed free-standing laterally-grown group III metal nitride boule 413 may include a similar or essentially identical composition as the ammonothermal group III metal nitride layer and etching may be performed under conditions where the etch rate of the back side of substrate 101 is much faster than the etch rate of the front surface of the ammonothermal group III metal nitride layer. The processed free-standing ammonothermal group III metal nitride boule 413 may include one or more window regions 415 that were formed above exposed regions 120, such as openings 112 in patterned mask layer(s) 111, on a substrate 101. The processed free-standing laterally-grown group III metal nitride boule 413 may also include one or more wing regions 417 that were formed above non-open regions in patterned mask layer(s) 111, and a pattern of locally-approximately-linear arrays 419 of threading dislocations, as shown in FIG. 4A. One or more of front surface 421 and back surface 423 of free-standing ammonothermal group III metal nitride boule 413 may be lapped, polished, etched, and chemical-mechanically polished. As similarly discussed above, the pattern of locally-approximately-linear arrays 419 may include a coalescence front region that includes a “sharp boundary” that has a width less than about 25 micrometers or less than about 10 micrometers that is disposed between the adjacent wing regions 417, or an “extended boundary” that has a width between about 25 micrometers and about 1000 micrometers or between about 30 micrometers and about 250 micrometers that is disposed between the adjacent wing regions 417, depending on the growth conditions.

In certain embodiments, the edge of the free-standing ammonothermal group III metal nitride boule 413 is ground to form a cylindrically-shaped ammonothermal group III metal nitride boule. In certain embodiments, one or more flats is ground into the side of free-standing ammonothermal group III metal nitride boule 413. In certain embodiments, free-standing ammonothermal group III metal nitride boule 413 is sliced into one or more free-standing ammonothermal group III metal nitride wafers 431, as shown in FIG. 4B. The slicing may be performed by multi-wire sawing, multi-wire slurry sawing, slicing, inner-diameter sawing, outer-diameter sawing, cleaving, ion implantation followed by exfoliation, spalling, laser cutting, or the like. One or more large-area surface of free-standing ammonothermal group III metal nitride wafers 431 may be lapped, polished, etched, electrochemically polished, photoelectrochemically polished, reactive-ion-etched, and/or chemical-mechanically polished according to methods that are known in the art. In certain embodiments, a chamfer, bevel, or rounded edge is ground into the edges of free-standing ammonothermal group III metal nitride wafers 431. The free-standing ammonothermal group III metal nitride wafers may have a diameter of at least about 5 millimeters, at least about 10 millimeters, at least about 25 millimeters, at least about 40 millimeters, at least about 50 millimeters, at least about 75 millimeters, at least about 100 millimeters, at least about 150 millimeters, at least about 200 millimeters, at least about 300 millimeters, at least about 400 millimeters, or at least about 600 millimeters and may have a thickness between about 50 micrometers and about 10 millimeters or between about 150 micrometers and about 1 millimeter. One or more large-area surface of free-standing ammonothermal group III metal nitride wafers 431 may be used as a substrate for group III metal nitride growth by chemical vapor deposition, metalorganic chemical vapor deposition, hydride vapor phase epitaxy, molecular beam epitaxy, flux growth, solution growth, ammonothermal growth, among others, or the like.

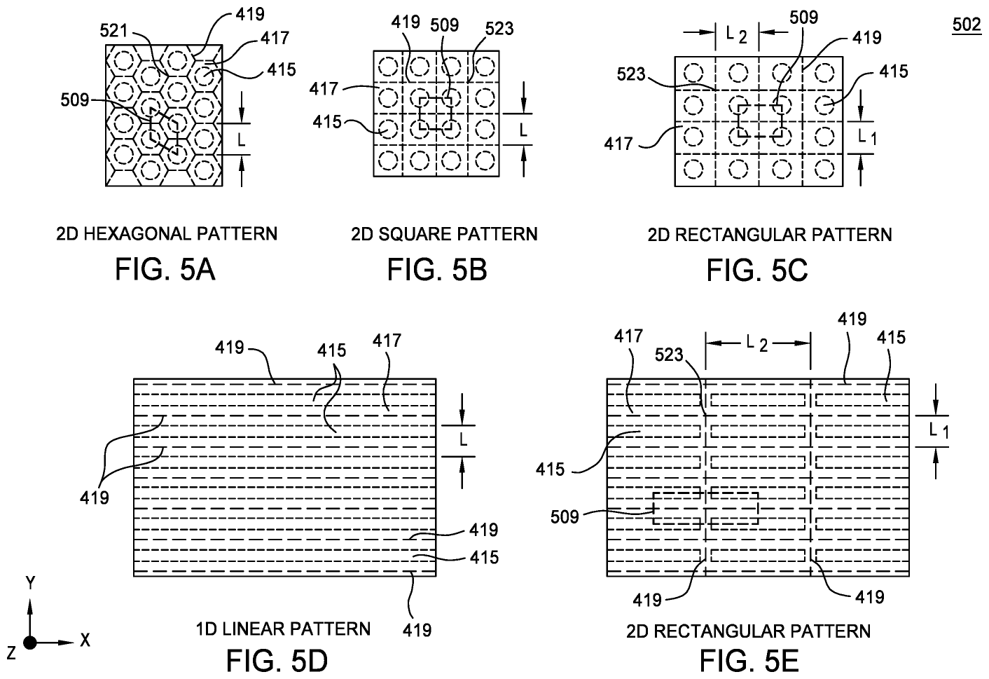

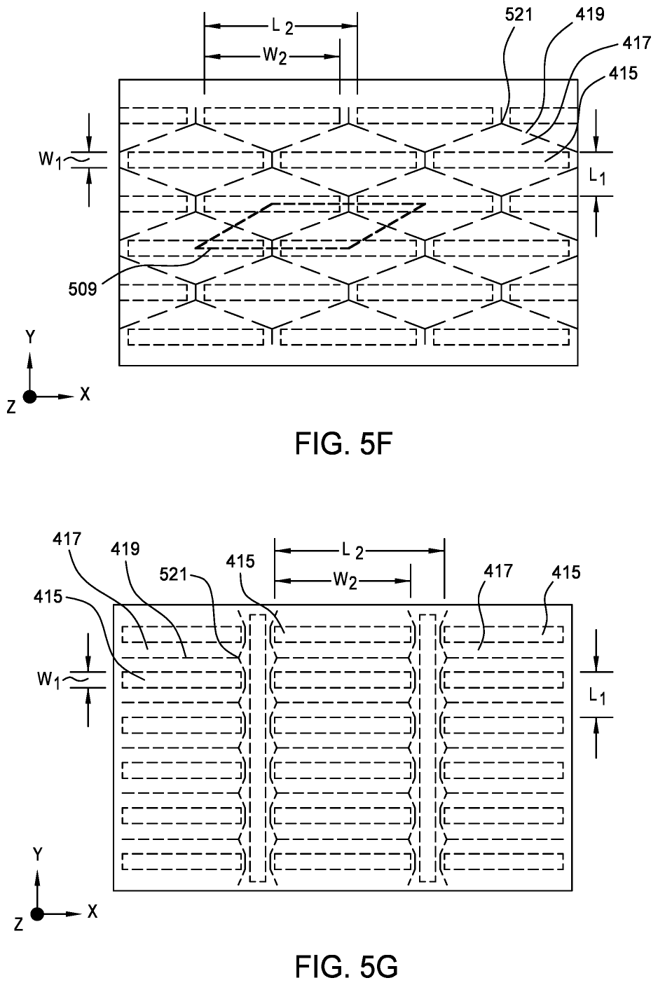

FIGS. 5A-5G and 8A-8E are simplified diagrams illustrating threading dislocation patterns formed in a free-standing group III metal nitride boule 413 or wafer 431, for example, after growth on seeds having a pattern of growth centers similar to those shown schematically in FIGS. 1F-1L and FIGS. 7A-7E, respectively. Crystals having the various patterns may have certain advantages and disadvantages, as described previously and also below. The large-area surfaces of the free-standing ammonothermal group III metal nitride boule 413 or wafers 431 may be characterized by a pattern of locally-approximately-linear arrays 419 of threading dislocations that propagated from coalescence fronts 219 formed during the epitaxial lateral overgrowth process, as discussed above in conjunction with FIGS. 3A-3F. The pattern of locally-approximately-linear arrays of threading dislocations may be 2D hexagonal, square, rectangular, trapezoidal, triangular, 1D linear, or an irregular pattern that is formed at least partially due to the pattern of the exposed regions 120 (FIGS. 1F-1L, 7A-7E) used during the process to form free-standing laterally-grown group III metal nitride boule 413. One or more window regions 415 are formed above the exposed regions 120 (FIGS. 1F-1 L, 7A-7E), and one or more wing regions 417 are formed on portions that are not above the exposed regions 120, that is, were formed by lateral growth. As discussed above, the formed coalescence fronts 219 or pattern of locally-approximately-linear arrays 419 may include coalescence front regions that have a lateral width (i.e., measured parallel to the surface of the page containing FIGS. 5A-5G and 8A-8E and perpendicular to the locally-approximately-linear arrays 419) that can vary depending on the growth conditions. In certain embodiments, the lateral width of coalescence fronts is between about 5 micrometers and about 500 micrometers, between about 10 micrometers and about 250 micrometers, or between about 20 micrometers and about 100 micrometers.

In certain embodiments, at least 15%, at least 40%, or at least 75% of intersections 521 between neighboring coalescence fronts 419 (also referred to herein as first regions) include or consist of three and only three coalescence fronts meeting at intersection angles of 120°±3°, as shown in FIGS. 5A, 5F, 5G, 8A, 8B, 8C, 8D, and 8E. For seeds having a near-c-plane orientation, for example, three-coalescence-front intersections may be formed by growth in the a-direction, which tends to be relatively fast, from neighboring growth centers. In certain embodiments, at least 50%, at least 75%, or at least 90% of intersections 523 between neighboring coalescence fronts 419 include or consist of four and only four coalescence fronts meeting at intersection angles of 90°±3°, as shown in FIGS. 5B, 5C, and 5E. These patterns, with four-coalescence-front vertices, may be particularly useful for growth of low-defect crystals having a nonpolar or semipolar orientation. In certain embodiments, at least 10%, at least 20%, or at least 30% of intersections 525 between neighboring coalescence fronts 419 include or consist of six coalescence fronts meeting at intersection angles of 60°±3°, as shown in FIGS. 8B, 8D, and 8E. Formation of six-coalescence-front intersections may be helpful in achieving maximum strain relaxation, but may require lateral growth in a relatively-slow direction in order to close voids. In certain embodiments, at least 10%, at least 15%, or at least 20% of intersections 527 between neighboring coalescence fronts 419 include or consist of two and only two coalescence fronts meeting at intersection angles of 120°±3°, as shown in FIGS. 8C and 8D. In certain embodiments, at least 10%, at least 15%, or at least 20% of intersections 529 between neighboring coalescence fronts 419 include or consist of three and only three coalescence fronts, where two of the coalescence fronts meet at an intersection angle of 120°±3°, and two of the coalescence fronts meet at an intersection angle of 90°±3°, as shown in FIG. 8D. In certain embodiments, at least 10%, at least 15%, or at least 20% of intersections 531 between neighboring coalescence fronts 419 include or consist of two and only two coalescence fronts meeting at an intersection angle of 150°±5°, as shown in FIG. 8E. In certain embodiments, at least 10%, at least 15%, or at least 20% of intersections 533 between neighboring coalescence fronts 419 include or consist of three and only three coalescence fronts, where two of the coalescence fronts meet at an intersection angle of 60°±3°, and two of the coalescence fronts meet at an intersection angle of 90°±3°, as shown in FIG. 8E. In certain embodiments, between about 3% and about 10% of intersections 535 between neighboring coalescence fronts 419 include or consist of four and only four coalescence fronts, where two of the coalescence fronts meet at an intersection angle of 60°±3°, two of the coalescence fronts meet at an intersection angle of 90°±3°, and two of the coalescence fronts meet at an intersection angle of 120°±3°, as shown in FIG. 8E. In certain embodiments, intersection type 535 is extended into two intersections joined by a short coalescence front, where the first intersection includes two coalescence fronts meeting at an intersection angle of 60°±3° and the second intersection includes two coalescence fronts meeting at an intersection angle of 120°±3°. The latter set of more complex coalescence-front intersections may arise due to the use of a more complicated mask pattern, such as those shown in FIG. 7C-7E, for example, and may enable an ideal combination of reliable coalescence and stress relaxation.

In certain embodiments, the mask pattern includes multiple domains having different orientations of growth centers 120, for example, like that shown schematically in FIG. 6. In such a case the resulting crystal may have patterns of dislocations within domains that are rotated with respect to neighboring domains. For example, locally, within a single domain, the distribution of threading dislocations may be similar to that shown in FIG. 5F, with the orientation of adjacent domains being rotated with respect to one another. In a specific embodiment, a first domain may be characterized by window regions 415 oriented in a first direction that is aligned within ±3° of a crystallographic orientation selected from <10−10> and <11−20>. The first domain may be surrounded by six domains, in which the direction of between 55% and 100% of the plurality of window regions 415 is oriented along a second direction, rotated by 60°±3° from the first direction, or along a third direction, rotated by 120°±3° from the first direction, where the direction of between 55% and 100% of the plurality of window regions 415 within the six surrounding domains alternate between the second direction and the third direction.

In certain embodiments, for example, the distributions of threading dislocations shown in FIGS. 5A and 8A-E, which arise from patterns with a triangular or hexagonal symmetry, as shown in FIGS. 1F and 7A-E, the average concentration of threading dislocations in a first direction (e.g., along the Y-direction in FIG. 5A and along the X-direction in FIGS. 8A-E) include a period of variation that varies periodically by at least a factor of two. In certain embodiments, the average concentration of threading dislocations also include a period of variation that varies periodically by at least a factor of two in each of a second direction and in a third direction, where the second direction is rotated by, or aligned at an angle of, 60 degrees from the first direction and the third direction rotated by, or aligned at an angle of, 120 degrees from the first direction. In certain embodiments, the periods of variation in each of the first direction, the second direction, and the third direction are equal, to within a factor of two, to within a factor of 1.5, to within a factor of 1.1 (that is, to within ±10%) or to within a factor of 1.05 (that is, to within ±5%).

In general, the distribution of window regions 415 within primitive unit cell 509, as illustrated schematically in FIGS. 5A-5G and 8A-8E, mirrors the distribution of pattern openings or growth centers in the mask, as shown schematically in FIGS. 1F-1L, 6, and 7A-7E and described above.

More complex patterns are also possible and may be advantageous, for example, in being more resistant to cracking or cleaving. The pattern 502 may be elongated in one direction compared to another orthogonal direction, for example, due to the free-standing laterally-grown group III metal nitride boule 413 being sliced at an inclined angle relative to the large-area surface (e.g., front surface 421, which is parallel to the X-Y plane) of a free-standing ammonothermal group III metal nitride boule 413. The pattern 502 of locally-approximately-linear arrays of threading dislocations may be characterized, in certain embodiments, by a linear array of threading dislocations (FIG. 5D) that have a pitch dimension L between about 5 micrometers and about 20 millimeters or between about 200 micrometers and about 5 millimeters. The pattern 502 of locally-approximately-linear arrays of threading dislocations may be characterized, in certain embodiments, by a pitch dimension L (FIGS. 5A, 5B), or by pitch dimensions L₁ and L₂ in two orthogonal directions (FIGS. 5C, 5E, 5F, and 5G), between about 5 micrometers and about 20 millimeters or between about 200 micrometers and about 5 millimeters, or between about 500 micrometers and about 2 millimeters. In certain embodiments, the pattern 502 of locally-approximately-linear arrays of threading dislocations is approximately aligned with the underlying crystal structure of the group III metal nitride, for example, with the locally-approximately-linear arrays lying within about 5 degrees, within about 2 degrees, or within about 1 degree of one or more of <1 0-1 0>, <1 1-2 0>, or [0 0 0±1] or their projections in the plane of the surface of the free-standing ammonothermal group III metal nitride boule 413 or group III metal nitride wafer 431. The linear concentration of threading dislocations in the pattern may be less than about 1×10⁵ cm⁻¹, less than about 3×10⁴ cm⁻¹, less than about 1×10⁴ cm⁻¹, less than about 3×10³ cm⁻¹, less than about 1×10³ cm⁻¹, less than about 3×10² cm⁻¹, or less than about 1×10² cm⁻¹. The linear concentration of threading dislocations in the pattern 502 may be greater than 5 cm⁻¹, greater than 10 cm⁻¹, greater than 20 cm⁻¹, greater than 50 cm⁻¹, greater than 100 cm⁻¹, greater than 200 cm⁻¹, or greater than 500 cm⁻¹.

Referring again to FIGS. 5A-5G and FIGS. 8A-8E, the large-area surfaces of the free-standing ammonothermal group III metal nitride boule or wafer may further be characterized by an array of wing regions 417 and by an array of window regions 415. Each wing region 417 may be positioned between adjacent locally-approximately-linear arrays 419 of threading dislocations. Each window region 415 may be positioned within a single wing region 417 or may be positioned between two adjacent wing regions 417 and may have a minimum dimension between 3 micrometers and 500 micrometers and be characterized by concentration of threading dislocations between 10³ cm⁻² and 10⁸ cm⁻², resulting from residual threading dislocations that propagated vertically from an exposed region (i.e., primary growth center) during the bulk crystal growth process, and by a concentration of stacking faults below 10³ cm⁻¹. The portion of a grown crystal that propagated vertically from an exposed region (e.g., window region) is also referred to herein as primary window regions, or alternatively as primary third regions. In some embodiments the boundary between the window regions and the wing regions may be decorated with dislocations, for example, with a line density between about 5 cm⁻¹ and 10⁵ cm⁻¹.

The arrays may be elongated in one direction compared to another orthogonal direction, for example, due to the boule being sliced at an inclined angle relative to the large-area surface of a free-standing ammonothermal group III metal nitride boule. The pattern of locally-approximately-linear arrays 419 of threading dislocations may be characterized by a pitch dimension L, or by pitch dimensions L₁ and L₂ in two orthogonal directions, between about 5 micrometers and about 20 millimeters or between about 200 micrometers and about 5 millimeters. In certain embodiments, the pattern of locally-approximately-linear arrays 419 of threading dislocations is approximately aligned with the underlying crystal structure of the group III metal nitride, for example, with the locally-approximately-linear arrays lying within about 5 degrees, within about 2 degrees, or within about 1 degree of one or more of <1 0−1 0>, <1 1−2 0>, or [0 0 0±1] or their projections in the plane of the surface of the free-standing ammonothermal group III nitride boule or wafer. The linear concentration of threading dislocations in the pattern may be less than about 1×10⁵ cm⁻¹, less than about 3×10⁴ cm⁻¹, less than about 1×10⁴ cm⁻¹, less than about 3×10³ cm⁻¹, less than about 1×10³ cm⁻¹, less than about 3×10² cm⁻¹, or less than about 1×10² cm⁻¹. The linear concentration of threading dislocations in the pattern may be greater than 5 cm⁻¹, greater than 10 cm⁻¹, greater than 20 cm⁻¹, greater than 50 cm⁻¹, greater than 100 cm⁻¹, greater than 200 cm⁻¹, or greater than 500 cm⁻¹.

The concentration of threading dislocations in the wing regions 417 between the locally-approximately-linear arrays of threading dislocations may be below about 10⁵ cm⁻², below about 10⁴ cm⁻², below about 10³ cm⁻², below about 10² cm⁻¹, or below about 10 cm⁻². The concentration of threading dislocations in the surface of the window regions 415 may be less than about 10⁸ cm⁻², less than about 10⁷ cm⁻², less than about 10⁶ cm⁻², less than about 10⁵ cm⁻², or less than about 10⁴ cm⁻². The concentration of threading dislocations in the surface of the window regions may be higher than the concentration of threading dislocations in the surface of the wing regions by at least a factor of two, by at least a factor of three, by at least a factor of ten, by at least a factor of 30, or by at least a factor of 100. The concentration of threading dislocations in the surface of the window regions may be higher than concentration of threading dislocations in the surface of the wing regions by less than a factor of 10⁴, by less than a factor of 3000, by less than a factor of 1000, by less than a factor of 300, by less than a factor of 100, or by less than a factor of 30. In some embodiments the boundary between the window regions 415 and the wing regions 417 may be decorated with dislocations, for example, with a line density between about 5 cm⁻¹ and 10⁵ cm⁻¹. The concentration of threading dislocations, averaged over a large area surface of the free-standing ammonothermal group III nitride boule or wafer, may be below about 10⁷ cm⁻², below about 10⁶ cm⁻², below about 10⁵ cm⁻², below about 10⁴ cm⁻², below about 10³ cm⁻², or below about 10² cm⁻². The concentration of stacking faults, averaged over a large area surface of the free-standing ammonothermal group III nitride boule or wafer, may be below about 10³ cm⁻¹, below about 10² cm⁻¹, below about 10 cm⁻¹, below about 1 cm⁻¹, or below about 0.1 cm⁻¹, or may be undetectable. In some embodiments, for example, after repeated re-growth on a seed crystal with a patterned array of dislocations and/or growth to a thickness greater than 2 millimeters, greater than 3 millimeters, greater than 5 millimeters, or greater than 10 millimeters, the positions of the threading dislocations may be displaced laterally to some extent with respect to the pattern on the seed crystal. In such a case the regions with a higher concentration of threading dislocations may be somewhat more diffuse than the relatively sharp lines illustrated schematically in FIGS. 5A-5G and FIGS. 8A-8E. However, the concentration of threading dislocations as a function of lateral position along a specified direction on the surface will vary periodically, with a period between about 5 micrometers and about 20 millimeters or between about 200 micrometers and about 5 millimeters. The concentration of threading dislocations within the periodically-varying region may vary by at least a factor of two, at least a factor of 5, at least a factor of 10, at least a factor of 30, at least a factor of 100, at least a factor of 300, or at least a factor of 1000.

The free-standing ammonothermal group III metal nitride boule or wafer may have a large-area crystallographic orientation within 5 degrees, within 2 degrees, within 1 degree, within 0.5 degree, within 0.2 degree, within 0.1 degree, within 0.05 degree, within 0.02 degree, or within 0.01 degree of (0001)+c-plane, (000-1)−c-plane, {10−10} m-plane, {1 1−2 0} a-plane, {11−2±2}, {60−6±1}, {50−5±1}, {40−4±1}, {30−3±1}, {50−5±2}, {70−7±3}, {20−2±1}, {30−3±2}, {40−4±3}, {50−5±4}, {10−1±1}, {1 0−1±2}, {1 0−1±3}, {2 1−3±1}, or {3 0−3±4}. The free-standing ammonothermal group III metal nitride boule or wafer may have an (h k i l) semipolar large-area surface orientation, where i=−(h+k) and l and at least one of h and k are nonzero.

In certain embodiments, a large-area surface of a free-standing ammonothermal group III metal nitride crystal or wafer has a crystallographic orientation that is miscut from {10-10} m-plane by between about −60 degrees and about +60 degrees toward [0001]+c-direction and by up to about 10 degrees toward an orthogonal<1-210> a-direction. In certain embodiments, a large-area surface of the free-standing ammonothermal group III metal nitride crystal or wafer has a crystallographic orientation that is miscut from {10-10} m-plane by between about −30 degrees and about +30 degrees toward [0001]+c-direction and by up to about 5 degrees toward an orthogonal<1-210> a-direction. In certain embodiments, a large-area surface of the free-standing ammonothermal group III metal nitride crystal or wafer has a crystallographic orientation that is miscut from {10-10} m-plane by between about −5 degrees and about +5 degrees toward [0001]+c-direction and by up to about 1 degree toward an orthogonal<1-210> a-direction. The free-standing ammonothermal group III metal nitride crystal or wafer may have a stacking fault concentration below 10² cm⁻¹, below 10 cm⁻¹, or below 1 cm⁻¹, and a very low dislocation density, below about 10⁵ cm⁻², below about 10⁴ cm⁻², below about 10³ cm⁻², below about 10² cm⁻², or below about 10 cm⁻² on one or both of the two large area surfaces.

The free-standing ammonothermal group III metal nitride boule or wafer may have a symmetric x-ray rocking curve full width at half maximum (FWHM) less than about 200 arcsec, less than about 100 arcsec, less than about 50 arcsec, less than about 35 arcsec, less than about 25 arcsec, or less than about 15 arcsec. The free-standing ammonothermal group III metal nitride boule or wafer may have a crystallographic radius of curvature greater than 0.1 meter, greater than 1 meter, greater than 10 meters, greater than 100 meters, or greater than 1000 meters, in at least one, at least two, or in three independent or orthogonal directions.

In certain embodiments, at least one surface of the free-standing ammonothermal group III metal nitride boule or wafer has atomic impurity concentrations of at least one of oxygen (O), and hydrogen (H) above about 1×10¹⁶ cm⁻³, above about 1×10¹⁷ cm⁻³, or above about 1×10¹⁸ cm⁻³. In certain embodiments, a ratio of the atomic impurity concentration of H to the atomic impurity concentration of 0 is between about 0.3 and about 1000, between about 0.4 and about 10, or between about 10 and about 100. In certain embodiments, at least one surface of the free-standing ammonothermal group III metal nitride boule or wafer has impurity concentrations of at least one of lithium (L₁), sodium (Na), potassium (K), fluorine (F), chlorine (Cl), bromine (Br), or iodine (I) above about 1×10¹⁵ cm⁻³, above about 1×10¹⁶ cm⁻³, or above about 1×10¹⁷ cm⁻³, above about 1×10¹⁹ cm⁻³. In certain embodiments, the top and bottom surfaces of the free-standing ammonothermal group III metal nitride boule or wafer may have impurity concentrations of O, H, carbon (C), Na, and K between about 1×10¹⁶ cm⁻³ and 1×10¹⁹ cm⁻³, between about 1×10¹⁶ cm⁻³ and 2×10¹⁹ cm⁻³, below 1×10¹⁷ cm⁻³, below 1×10¹⁶ cm⁻³, and below 1×10¹⁶ cm⁻³, respectively, as quantified by calibrated secondary ion mass spectrometry (SIMS). In another embodiment, the top and bottom surfaces of the free-standing ammonothermal group III metal nitride boule or wafer may have impurity concentrations of O, H, C, and at least one of Na and K between about 1×10¹⁶ cm⁻³ and 1×10¹⁶ cm⁻³, between about 1×10¹⁶ cm⁻³ and 2×10¹⁶ cm⁻³, below 1×10¹⁷ cm⁻³, and between about 3×10¹⁵ cm⁻³ and 1×10¹⁸ cm⁻³, respectively, as quantified by calibrated secondary ion mass spectrometry (SIMS). In still another embodiment, the top and bottom surfaces of the free-standing ammonothermal group III metal nitride boule or wafer may have impurity concentrations of O, H, C, and at least one of F and CI between about 1×10¹⁶ cm⁻³ and 1×10¹⁹ cm⁻³, between about 1×10¹⁶ cm⁻³ and 2×10¹⁶ cm⁻³, below 1×10¹⁷ cm⁻³, and between about 1×10¹⁶ cm⁻³ and 1×10¹⁶ cm⁻³, respectively, as quantified by calibrated secondary ion mass spectrometry (SIMS). In some embodiments, the top and bottom surfaces of the free-standing ammonothermal group III metal nitride boule or wafer may have impurity concentrations of H between about 5×10¹⁷ cm⁻³ and 1×10¹⁹ cm⁻³, as quantified by calibrated secondary ion mass spectrometry (SIMS). In certain embodiments, at least one surface of the free-standing ammonothermal group III metal nitride boule or wafer has an impurity concentration of copper (Cu), manganese (Mn), and iron (Fe) between about 1×10₁₆ cm⁻³ and 1×10¹⁹ cm⁻³. In a specific embodiment, the free-standing ammonothermal group III metal nitride boule or wafer has an infrared absorption peak at about 3175 cm⁻¹, with an absorbance per unit thickness of greater than about 0.01 cm⁻¹.

The free-standing ammonothermal group III metal nitride crystal or wafer may be characterized by a wurtzite structure substantially free from any cubic entities or other crystal structures, the other structures being less than about 0.1% in volume in reference to the substantially wurtzite structure.

Surprisingly, given the lattice mismatch between HVPE GaN and ammonothermal GaN, results of use of the herein-disclosed techniques show that ammonothermal lateral epitaxial overgrowth is capable of producing thick, large-area GaN layers that are free of cracks. In certain embodiments, the free-standing ammonothermal group III metal nitride crystal or wafer has a diameter larger than about 25 millimeters, larger than about 50 millimeters, larger than about 75 millimeters, larger than about 100 millimeters, larger than about 150 millimeters, larger than about 200 millimeters, larger than about 300 millimeters, or larger than about 600 millimeters, and a thickness greater than about 0.1 millimeter, greater than about 0.2 millimeter, greater than about 0.3 millimeter, greater than about 0.5 millimeter, greater than about 1 millimeter, greater than about 2 millimeters, greater than about 3 millimeters, greater than about 5 millimeters, greater than about 10 millimeters, or greater than about 20 millimeters, and is substantially free of cracks. By contrast, we find that ammonothermal growth on large-area, un-patterned HVPE GaN seed crystals often leads to cracking if the layers are thicker than a few hundred microns, even if a patterning process had been used to form the HVPE GaN seed crystal.

A free-standing ammonothermal group Ill metal nitride wafer may be characterized by a total thickness variation (TTV) of less than about 25 micrometers, less than about 10 micrometers, less than about 5 micrometers, less than about 2 micrometers, or less than about 1 micrometer, and by a macroscopic bow that is less than about 200 micrometers, less than about 100 micrometers, less than about 50 micrometers, less than about 25 micrometers, or less than about 10 micrometers. A large-area surface of the free-standing ammonothermal group Ill metal nitride wafer may have a concentration of macro defects, with a diameter or characteristic dimension greater than about 100 micrometers, of less than about 2 cm⁻², less than about 1 cm⁻², less than about 0.5 cm⁻², less than about 0.25 cm⁻², or less than about 0.1 cm⁻². The variation in miscut angle across a large-area surface of the free-standing ammonothermal group Ill metal nitride crystal or wafer may be less than about 5 degrees, less than about 2 degrees, less than about 1 degree, less than about 0.5 degree, less than about 0.2 degree, less than about 0.1 degree, less than about 0.05 degree, or less than about 0.025 degree in each of two orthogonal crystallographic directions. The root-mean-square surface roughness of a large-area surface of the free-standing ammonothermal group Ill metal nitride wafer, as measured over an area of at least 10 μm×10 μm, may be less than about 0.5 nanometer, less than about 0.2 nanometer, less than about 0.15 nanometer, less than about 0.1 nanometer, or less than about 0.10 nanometer. The free-standing ammonothermal group Ill metal nitride wafer may be characterized by n-type electrical conductivity, with a carrier concentration between about 1×10¹⁷ cm⁻³ and about 3×10¹⁹ cm⁻³ and a carrier mobility greater than about 100 cm²/V-s. In alternative embodiments, the free-standing ammonothermal group III metal nitride wafer is characterized by p-type electrical conductivity, with a carrier concentration between about 1×10¹⁵ cm⁻³ and about 1×10¹⁹ cm⁻³. In still other embodiments, the free-standing ammonothermal group III metal nitride wafer is characterized by semi-insulating electrical behavior, with a room-temperature resistivity greater than about 10⁷ ohm-centimeter, greater than about 10⁸ ohm-centimeter, greater than about 10⁹ ohm-centimeter, greater than about 10¹⁰ ohm-centimeter, or greater than about 10¹¹ ohm-centimeter. In certain embodiments, the free-standing ammonothermal group III metal nitride wafer is highly transparent, with an optical absorption coefficient at a wavelength of 400 nanometers that is less than about 10 cm⁻¹, less than about 5 cm⁻¹, less than about 2 cm⁻¹, less than about 1 cm⁻¹, less than about 0.5 cm⁻¹. less than about 0.2 cm⁻¹, or less than about 0.1 cm⁻¹.

In some embodiments, the free-standing ammonothermal group III metal nitride crystal or wafer is used as a seed crystal for further bulk growth. In one specific embodiment, the further bulk growth comprises ammonothermal bulk crystal growth. In another specific embodiment, the further bulk growth comprises high temperature solution crystal growth, also known as flux crystal growth. In yet another specific embodiment, the further bulk growth comprises HVPE. The further-grown crystal may be sliced, lapped, polished, etched, and/or chemically-mechanically polished into wafers by methods that are known in the art. The surface of the wafers may be characterized by a root-mean-square surface roughness measured over a 10-micrometer by 10-micrometer area that is less than about 1 nanometer or less than about 0.2 nanometers.

The above sequence of steps provides a method according to an embodiment of the present disclosure. In a specific embodiment, the present disclosure provides a method and resulting crystalline material provided by a high pressure apparatus having structured support members. Other alternatives can also be provided where steps are added, one or more steps are removed, or one or more steps are provided in a different sequence without departing from the scope of the claims herein.

While the foregoing is directed to embodiments of the present disclosure, other and further embodiments of the disclosure may be devised without departing from the basic scope thereof, and the scope thereof is determined by the claims that follow.

What is claimed is:

1. A crystal, comprising a group Ill metal and nitrogen, wherein the crystal is free-standing and comprises:
a wurtzite crystal structure;
a first surface having a maximum dimension greater than 5 millimeters in a first direction, the first surface having a crystallographic orientation within 5 degrees of one of (0001) and (000-1);
an average concentration of stacking faults below 10³ cm⁻¹; and
an average concentration of threading dislocations between 10¹ cm⁻² and 10⁶ cm⁻², wherein the average concentration of threading dislocations on the first surface varies periodically by at least a factor of two in the first direction within a first domain, the period of the variation in the first direction being between 5 micrometers and 20 millimeters and the first domain having a maximum dimension in the first direction greater than 500 micrometers, wherein
the first surface comprises a plurality of first regions, each of the plurality of first regions having a locally-approximately-linear array of threading dislocations with a concentration between 5 cm⁻¹ and 10⁵ cm⁻¹, and at least 50% of intersections between neighboring locally-approximately-linear arrays of threading dislocations consist essentially of three locally-approximately-linear arrays of threading dislocations meeting at intersection angles of 120°±3°,
the first surface further comprises a plurality of second regions, each of the plurality of second regions being disposed between an adjacent pair of the plurality of first regions and having a concentration of threading dislocations below 10⁵ cm⁻² and a concentration of stacking faults below 10³ cm⁻¹, and
the first surface further comprises a plurality of third regions, each of the plurality of third regions being disposed within one of the plurality of second regions or between an adjacent pair of second regions and having a minimum dimension between 3 micrometers and 5 millimeters and threading dislocations with a concentration between 10³ cm⁻² and 10⁸ cm⁻².

2. The crystal of claim 1, wherein the crystal further comprises an impurity concentration of H greater than 10¹⁷ cm⁻³, and an impurity concentration of at least one of Li, Na, K, F, Cl, Br, and I greater than 10¹⁵ cm⁻³, as quantified by calibrated secondary ion mass spectrometry.

3. The crystal of claim 2, wherein the first surface is characterized by impurity concentrations of:
oxygen (O) between 1×10¹⁶ cm⁻³ and 1×10¹⁹ cm⁻³;
hydrogen (H) between 1×10¹⁶ cm⁻³ and 2×10¹⁹ cm⁻³; and
at least one of fluorine (F) and chlorine (Cl) between 1×10¹⁵ cm⁻³ and 1×10¹⁹ cm⁻³.

4. The crystal of claim 2, wherein the first surface is characterized by impurity concentrations of:
oxygen (O) between 1×10¹⁶ cm⁻³ and 1×10¹⁹ cm⁻³;
hydrogen (H) between 1×10¹⁶ cm⁻³ and 2×10¹⁹ cm⁻³; and
at least one of sodium (Na) and potassium (K) between 3×10¹⁵ cm⁻³ and 1×10¹⁵ cm⁻³.

5. The crystal of claim 1, wherein an overlap between neighboring third regions, which are included among the plurality of third regions, that are aligned in a second direction that is orthogonal to the first direction and that are adjacent in the first direction, is between \sqrt{3} and 3\sqrt{3} times the separation between adjacent third regions in the first direction.

6. The crystal of claim 1, wherein the first domain is surrounded by six domains, in which the direction of between 55% and 100% of the plurality of third regions is oriented along a second direction, aligned at an angle of 60°±3° from the first direction, or along a third direction, aligned at an angle of 120°±3° from the first direction, where the direction of between 55% and 100% of the plurality of third regions within the six surrounding domains alternate between the second direction and the third direction.

7. A crystal, comprising a group Ill metal and nitrogen, wherein the crystal is free-standing and comprises:
a wurtzite crystal structure;
a first surface having a maximum dimension greater than 5 millimeters in a first direction, the first surface having a crystallographic orientation within 5 degrees of one of (0001) and (000-1) and the first direction being aligned within ±3° of a crystallographic orientation selected from <10-10> and <11-20>;
an average concentration of stacking faults below 10³ cm⁻¹; and
an average concentration of threading dislocations between 10¹ cm⁻² and 10⁶ cm⁻², wherein the average concentration of threading dislocations on the first surface comprises periods of variation that vary periodically by at least a factor of two in each of the first direction, a second direction aligned at an angle of 60 degrees from the first direction, and third direction aligned at an angle of 120 degrees from the first direction, the periods of variation in the first direction, the second direction, and the third direction being equal, to within a factor of two, and each being between 5 micrometers and 20 millimeters; wherein
the first surface comprises a plurality of first regions, each of the plurality of first regions having a locally-approximately-linear array of threading dislocations with a concentration between 5 cm⁻¹ and 10⁵ cm⁻¹, and between 5% and 75% of intersections between neighboring locally-approximately-linear arrays of threading dislocations comprising three and only three locally-approximately-linear arrays of threading dislocations meeting at intersection angles of 120°±3°,
the first surface further comprises a plurality of second regions, each of the plurality of second regions being at least partially disposed between an adjacent pair of the plurality of first regions and having a concentration of threading dislocations below 10⁵ cm⁻² and a concentration of stacking faults below 10³ cm⁻¹, and
the first surface further comprises a plurality of third regions, each of the plurality of third regions being disposed within one of the plurality of second regions or at least partially disposed between an adjacent pair of second regions and having a minimum dimension between 3 micrometers and 5 millimeters and threading dislocations with a concentration between 10³ cm⁻² and 10⁸ cm⁻².

8. The crystal of claim 7, wherein the crystal further comprises an impurity concentration of H greater than 10¹⁷ cm⁻³, and an impurity concentration of at least one of Li, Na, K, F, Cl, Br, and I greater than 10¹⁵ cm⁻³, as quantified by calibrated secondary ion mass spectrometry.

9. The crystal of claim 8, wherein the first surface is characterized by impurity concentrations of:
oxygen (O) between 1×10¹⁶ cm⁻³ and 1×10¹⁹ cm⁻³;
hydrogen (H) between 1×10¹⁶ cm⁻³ and 2×10¹⁹ cm⁻³; and
at least one of fluorine (F) and chlorine (Cl) between 1×10¹⁵ cm⁻³ and 1×10¹⁹ cm⁻³.

10. The crystal of claim 8, wherein the first surface is characterized by impurity concentrations of:
oxygen (O) between 1×10¹⁶ cm⁻³ and 1×10¹⁹ cm⁻³;
hydrogen (H) between 1×10¹⁶ cm⁻³ and 2×10¹⁹ cm⁻³; and
at least one of sodium (Na) and potassium (K) between 3×10¹⁵ cm⁻³ and 1×10¹⁸ cm⁻³

11. The crystal of claim 7, wherein periods of variation in each of the first direction, the second direction, and the third directions are equal to within 10%.

12. The crystal of claim 7, wherein the plurality of third regions comprise a plurality of primary third regions, each of the plurality of primary third regions having a rectangular shape with a short dimension between about 3 micrometers and about 100 micrometers and a long dimension between about 200 micrometers and about 5 millimeters, wherein
the plurality of primary third regions comprise:
a first linear array of primary third regions that are aligned parallel to the first direction,
a second linear array of primary third regions that are aligned parallel to the second direction, and
a third linear array of primary third regions that are aligned parallel to the third direction,
the first linear array of primary third regions is intersected by the linear arrays of primary third regions aligned parallel to the two other directions, and
wherein a linear sequence of the intersections comprise intersections where a primary third region in the first linear array extends through a first intersection in the sequence of the intersections, a primary third region in the second linear array extends through a second intersection in the sequence of the intersections, and a primary third region in the third linear array extends through a third intersection in the sequence of the intersections.

13. The crystal of claim 7, wherein the plurality of third regions comprise a plurality of primary third regions that define a primitive unit cell, wherein the primitive unit cell contains three intersections where first primary third regions of the plurality of primary third regions in the first direction are intersected by lines extending primary third regions in the second direction and in the third direction, three intersections where first primary third regions in the second direction are intersected by lines extending primary third regions in the first direction and in the third direction, and three intersections where first primary third regions in the third direction are intersected by lines extending primary third regions in the first direction and in the second direction.

14. The crystal of claim 7, wherein the plurality of third regions comprises a plurality of primary third regions, each of the primary third regions having a rectangular shape with a short dimension between about 3 micrometers and about 100 micrometers and a long dimension between about 200 micrometers and about 5 millimeters, wherein each of the plurality of primary third regions are parallel to lines in the first direction, the second direction, or the third direction, and a first end of each of the primary third regions points toward a central portion of a neighboring primary third region and a second end of each of the primary third regions points toward an end portion of another neighboring primary third region.

15. The crystal of claim 7, wherein the plurality of third regions comprises a plurality of primary third regions and a plurality of secondary third regions, wherein the plurality of primary third regions define a two-dimensional periodic array having a primitive unit cell and at least three secondary third regions are contained within the primitive unit cell.

16. The crystal of claim 7, wherein the plurality of third regions comprise:
a two-dimensional pattern of third regions that comprises a repeating unit of third regions, wherein each repeating unit comprises:
a portion of a first linear array of primary third regions, wherein the first linear array extends in the first direction;
a portion of a second linear array of primary third regions, wherein second linear array extends in the second direction;
a portion of a third linear array of two or more primary third regions, wherein the third linear array extends in the third direction, and the first linear array, the second linear array and the third linear array of the primary third regions cross at an intersection point,
wherein each of the primary third regions have a rectangular shape with a short dimension between about 3 micrometers and about 100 micrometers and a long dimension between about 200 micrometers and about 5 millimeters.

17. The crystal of claim 16, wherein the repeating units of the third regions are formed in a linear sequence of repeating units, wherein the portions of the primary third regions within the linear sequence of repeating units are sequentially aligned in the first direction, aligned at an angle of 60 degrees from the first direction, and aligned at an angle of 120 degrees from the first direction.

18. The crystal of claim 16, wherein the repeating unit of third regions further comprises a plurality of secondary third regions, wherein the secondary third regions comprise two intersecting third regions that are oriented at an angle to each other.

19. The crystal of claim 16, wherein a primary third region in the first linear array of primary third regions extends through the intersection point.

20. The crystal of claim 7, wherein the plurality of third regions comprise:
a two-dimensional array of primary third regions, wherein
the primary third regions within the two-dimensional array have a rectangular shape with a short dimension between about 3 micrometers and about 100 micrometers and a long dimension between about 200 micrometers and about 5 millimeters,
a first end of each of the primary third regions is positioned a first distance from a central point, and
each primary third region is oriented so that a line that extends through the center of each primary third region and is parallel to the long dimension of the primary third region is not coincident with the central point.
